(19) United States
(12) Patent Application Publication
(10) Pub. No.: US 2003/0034538 A1
(43) Pub. Date: Feb. 20, 2003

(54) Tunable laser array in composite integrated circuitry

(75) Inventors: Timothy J. Brophy, Holland, PA (US); Barbara Foley Barenburg, Gilbert, AZ (US); Amarildo Vieira, Philadelphia, PA (US); Kerry I. Litvin, Huntingdon Valley, PA (US)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MOTOROLA, INC., Schaumburg, IL (US)

(21) Appl. No.: 09/929,748

(22) Filed: Aug. 15, 2001

(51) Int. Cl. H01L 31/00

(52) U.S. Cl. 257/444

(57) ABSTRACT

High quality epitaxial layers of compound semiconductor materials can be grown overlying large silicon wafers by first growing an accommodating buffer layer on a silicon wafer. An accommodating buffer layer comprises a layer of monocrystalline oxide spaced apart from a silicon wafer by an amorphous interface layer of silicon oxide. The amorphous interface layer dissipates strain and permits the growth of a high quality monocrystalline oxide accommodating buffer layer. The accommodating buffer layer is lattice matched to both the underlying silicon wafer and the overlying monocrystalline compound semiconductor layer. Any lattice mismatch between the accommodating buffer layer and the underlying silicon substrate is taken care of by the amorphous interface layer. A composite integrated circuit having a tunable laser is provided. The laser may be mode-locked. Injection-locking may be used to pass optical properties to a slave laser. An array of lasers may provide different optical outputs into one or more waveguides.

### FIELD OF THE INVENTION

This invention generally relates to semiconductor structures and devices, and more particularly to composite integrated circuits for one or more tunable laser sources.

### BACKGROUND OF THE INVENTION

As conventional telecommunications and data communication converges, there is a need for transmitter and receiver arrays able to handle parallel communications. Vertical cavity surface emitting lasers (VCSELs) have been fabricated in array format for applications such as data communication. Because an optical beam is emitted perpendicular to the wafer surface, VCSEL arrays can match parallel fiber ribbons and have been used for short-haul computer interconnection.

As the demand for higher data rates and long haul applications increases, it will be necessary to improve the signal quality of these arrays in terms of their amplitude and phase noise. The optical quality of a laser can be improved by techniques such as laser mode-locking and optical injection-locking. Moreover, with the eventual convergence with wavelength division multiplexing (WDM) systems, wavelength tunability of the different transmitters may also be necessary.

When the phases of an electro-magnetic field of an optical resonator, such as a laser, are fixed, the electromagnetic field exhibits periodic properties. The total optical field of a laser is represented as:

E(t)=ΣₙEₙe^{i[ω}^{₀}^{+nω)t+φn}^{]}

where the summation is over the modes under the gain curve of the resonator and n indicates the mode number. Eₙ and φₙ are the amplitude and phase of the nth mode, respectively. E(t) is periodic in T=2π/ω=2L/c (i.e., the round trip transit time of the light in the laser's cavity), where L is the length of the resonator. If the phases are fixed to some φₙ then E(t)=E(t+T). This is explored in further detail in Yariv, “Optical Electronics,” p. 193.

Phases are likely to vary in a typical laser, thus creating random fluctuations in the electro-magnetic field. A known way to remove this fluctuation, in cases where high coherence is required, is to make the cavity of the laser small, so that all but one mode are removed from under the gain curve. In this particular case, the laser is said to be in single-mode.

In the case of a multi-mode laser, the phases of the different modes can be forced to maintain a relatively constant value by a technique called mode-locking. Mode-locking may be obtained by modulating the loss or gain of a laser at the radian frequency ω=πc/L (i.e., the intermode frequency spacing). If mode-locking occurs, power is emitted in pulses with a period T=2π/ω=2L/c, the round-trip delay time of the laser cavity. Peak power will be equal to the average power of the laser times the number of modes locked together. The length of the mode-locked pulse is approximately the inverse of the gain linewidth.

A typical arrangement used for mode-locking a laser includes a long cavity having the traditional gain material contained therein with mirrors at both ends. An amplitude modulator (i.e., for use in AM mode-locking) or a phase modulator (i.e., for use in FM mode-locking) is placed in the cavity and is driven to a rate that is equivalent to the rate at which the modes of the laser propagate. Another known implementation of mode-locking a laser involves placing a non-linear device such as a saturable absorber in the cavity to provide a perturbation that essentially removes unwanted modes from the laser.

### BRIEF DESCRIPTION OF THE DRAWINGS

FIGS. 1, 2, 3, 24, 25 illustrate schematically, in cross section, device structures that can be used in accordance with various embodiments of the invention.

FIG. 4 illustrates graphically the relationship between maximum attainable film thickness and lattice mismatch between a host crystal and a grown crystalline overlayer.

FIG. 5 is a high resolution Transmission Electron Micrograph (TEM) of illustrative semiconductor material manufactured in accordance with what is shown herein.

FIG. 6 is an x-ray diffraction taken on an illustrative semiconductor structure manufactured in accordance with what is shown herein.

FIG. 7 illustrates a high resolution Transmission Electron Micrograph of a structure including an amorphous oxide layer.

FIG. 8 illustrates an x-ray diffraction spectrum of a structure including an amorphous oxide layer.

FIGS. 9-12 illustrate schematically, in cross-section, the formation of a device structure in accordance with another embodiment of the invention.

FIGS. 13-16 illustrate a probable molecular bonding structure of the device structures illustrated in FIGS. 9-12.

FIGS. 17-20 illustrate schematically, in cross-section, the formation of a device structure in accordance with still another embodiment of the invention.

FIGS. 21-23 illustrate schematically, in cross section, the formation of a yet another embodiment of a device structure in accordance with the invention.

FIGS. 26-30 include illustrations of cross-sectional views of a portion of an integrated circuit that includes a compound semiconductor portion, a bipolar portion, and a MOS portion in accordance with what is shown herein.

FIGS. 31-37 include illustrations of cross-sectional views of a portion of another integrated circuit that includes a semiconductor laser and a MOS transistor in accordance with what is shown herein.

FIG. 38 is a simplified plan view of a conventional semiconductor integrated circuit.

FIG. 39 is a simplified cross-sectional view of an exemplary embodiment of an optical bus in accordance with what is shown herein.

FIG. 40 is a simplified plan view of an exemplary embodiment of an integrated circuit employing the optical bus of FIG. 39 in accordance with what is shown herein.

FIG. 41 is a simplified cross-sectional view of other exemplary embodiments of the optical bus of FIG. 39 in accordance with what is shown herein.

FIG. 42 is a simplified plan view of an exemplary embodiment of a beam splitter shown in FIG. 40 in accordance with what is shown herein.

FIG. 43 is a simplified plan view of an illustrative tunable laser in accordance with what is shown herein.

FIG. 44 is a simplified cross-sectional view of an illustrative embodiment of gratings used as mirrors in accordance with what is shown herein.

FIG. 45 is a simplified cross-sectional view of another illustrative embodiment of gratings used as mirrors in accordance with what is shown herein.

FIG. 46 is a simplified plan view of an illustrative injection-locked arrangement of lasers in accordance with what is shown herein.

FIG. 47 is a simplified plan view of an illustrative laser array in accordance with what is shown herein.

FIG. 48 is a simplified plan view of an illustrative injection-locked laser array in accordance with what is shown herein.

FIG. 49 is a simplified plan view of an illustrative injection-locking arrangement having one master laser and multiple slave lasers in accordance with what is shown herein.

FIG. 50 is a simplified plan view of an illustrative arrangement in which multiple outputs from an array of lasers is combined into one waveguide in accordance with what is shown herein.

FIG. 51 is a simplified plan view of an illustrative arrangement to produce RF or millimeter waves from single-mode lasers in accordance with what is shown herein.

FIG. 52 is a simplified plan view of an illustrative arrangement to produce RF or millimeter waves from a multi-mode laser in accordance with what is shown herein.

FIGS. 53-58 are flow charts of illustrative steps involved in fabricating tunable lasers in accordance with what is shown herein.

Skilled artisans will appreciate that in many cases elements in certain FIGs. are illustrated for simplicity and clarity and have not necessarily been drawn to scale. For example, the dimensions of some of the elements in certain FIGs. may be exaggerated relative to other elements to help to improve understanding of what is being shown.

### DETAILED DESCRIPTION OF THE DRAWINGS

The present invention involves semiconductor structures of particular types. For convenience herein, these semiconductor structures are sometimes referred to as “composite semiconductor structures” or “composite integrated circuits” because they include two (or more) significantly different types of semiconductor devices in one integrated structure or circuit. For example, one of these two types of devices may be silicon-based devices such as CMOS devices, and the other of these two types of devices may be compound semiconductor devices such GaAs devices.

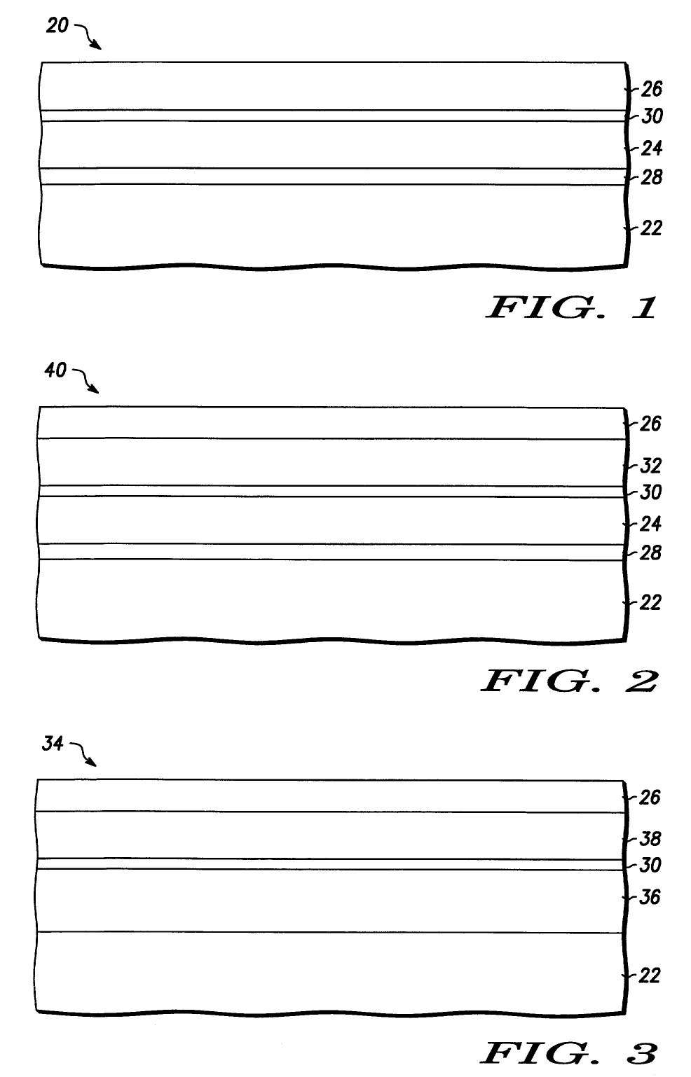

FIG. 1 illustrates schematically, in cross section, a portion of a semiconductor structure 20 which may be relevant to or useful in connection with certain embodiments of the present invention. Semiconductor structure 20 includes a monocrystalline substrate 22, accommodating buffer layer 24 comprising a monocrystalline material, and a layer 26 of a monocrystalline compound semiconductor material. In this context, the term “monocrystalline” shall have the meaning commonly used within the semiconductor industry. The term shall refer to materials that are a single crystal or that are substantially a single crystal and shall include those materials having a relatively small number of defects such as dislocations and the like as are commonly found in substrates of silicon or germanium or mixtures of silicon and germanium and epitaxial layers of such materials commonly found in the semiconductor industry.

In accordance with one embodiment, structure 20 also includes an amorphous intermediate layer 28 positioned between substrate 22 and accommodating buffer layer 24. Structure 20 may also include a template layer 30 between accommodating buffer layer 24 and compound semiconductor layer 26. As will be explained more fully below, template layer 30 helps to initiate the growth of compound semiconductor layer 26 on accommodating buffer layer 24. Amorphous intermediate layer 28 helps to relieve the strain in accommodating buffer layer 24 and by doing so, aids in the growth of a high crystalline quality accommodating buffer layer 24.

Substrate 22, in accordance with one embodiment, is a monocrystalline semiconductor wafer, preferably of large diameter. The wafer can be of a material from Group IV of the periodic table. Examples of Group IV semiconductor materials include silicon, germanium, mixed silicon and germanium, mixed silicon and carbon, mixed silicon, germanium and carbon, and the like. Preferably substrate 22 is a wafer containing silicon or germanium, and most preferably is a high quality monocrystalline silicon wafer as used in the semiconductor industry. Accommodating buffer layer 24 is preferably a monocrystalline oxide or nitride material epitaxially grown on the underlying substrate 22. In accordance with one embodiment, amorphous intermediate layer 28 is grown on substrate 22 at the interface between substrate 22 and the growing accommodating buffer layer 24 by the oxidation of substrate 22 during the growth of layer 24. Amorphous intermediate layer 28 serves to relieve strain that might otherwise occur in monocrystalline accommodating buffer layer 24 as a result of differences in the lattice constants of substrate 22 and buffer layer 24. As used herein, lattice constant refers to the distance between atoms of a cell measured in the plane of the surface. If such strain is not relieved by amorphous intermediate layer 28, the strain may cause defects in the crystalline structure of accommodating buffer layer 24. Defects in the crystalline structure of accommodating buffer layer 24, in turn, would make it difficult to achieve a high quality crystalline structure in monocrystalline compound semiconductor layer 26.

Accommodating buffer layer 24 is preferably a monocrystalline oxide or nitride material selected for its crystalline compatibility with underlying substrate 22 and with overlying compound semiconductor material 26. For example, the material could be an oxide or nitride having a lattice structure matched to substrate 22 and to the subsequently applied semiconductor material 26. Materials that are suitable for accommodating buffer layer 24 include metal oxides such as the alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, alkaline earth metal tin-based perovskites, lanthanum aluminate, lanthanum scandium oxide, and gadolinium oxide. Additionally, various nitrides such as gallium nitride, aluminum nitride, and boron nitride may also be used for accommodating buffer layer 24. Most of these materials are insulators, although strontium ruthenate, for example, is a conductor. Generally, these materials are metal oxides or metal nitrides, and more particularly, these metal oxide or nitrides typically include at least two different metallic elements. In some specific applications, the metal oxides or nitride may include three or more different metallic elements.

Amorphous interface layer 28 is preferably an oxide formed by the oxidation of the surface of substrate 22, and more preferably is composed of a silicon oxide. The thickness of layer 28 is sufficient to relieve strain attributed to mismatches between the lattice constants of substrate 22 and accommodating buffer layer 24. Typically, layer 28 has a thickness in the range of approximately 0.5-5 nm.

The compound semiconductor material of layer 26 can be selected, as needed for a particular semiconductor structure, from any of the Group IIIA and VA elements (III-V semiconductor compounds), mixed III-V compounds, Group II(A or B) and VIA elements (II-VI semiconductor compounds), and mixed II-VI compounds. Examples include gallium arsenide (GaAs), gallium indium arsenide (GaInAs), gallium aluminum arsenide (GaAlAs), indium phosphide (InP), cadmium sulfide (CdS), cadmium mercury telluride (CdHgTe), zinc selenide (ZnSe), zinc sulfur selenide (ZnSSe), and the like. Suitable template 30 materials chemically bond to the surface of the accommodating buffer layer 24 at selected sites and provide sites for the nucleation of the epitaxial growth of the subsequent compound semiconductor layer 26. Appropriate materials for template 30 are discussed below.

FIG. 2 illustrates, in cross section, a portion of a semiconductor structure 40 in accordance with a further embodiment. Structure 40 is similar to the previously described semiconductor structure 20 except that an additional buffer layer 32 is positioned between accommodating buffer layer 24 and layer of monocrystalline compound semiconductor material 26. Specifically, additional buffer layer 32 is positioned between the template layer 30 and the overlying layer 26 of compound semiconductor material. Additional buffer layer 32, formed of a semiconductor or compound semiconductor material, serves to provide a lattice compensation when the lattice constant of accommodating buffer layer 24 cannot be adequately matched to the overlying monocrystalline compound semiconductor material layer 26.

FIG. 3 schematically illustrates, in cross section, a portion of a semiconductor structure 34 in accordance with another exemplary embodiment of the invention. Structure 34 is similar to structure 20, except that structure 34 includes an amorphous layer 36, rather than accommodating buffer layer 24 and amorphous interface layer 28, and an additional semiconductor layer 38.

As explained in greater detail below, amorphous layer 36 may be formed by first forming an accommodating buffer layer and an amorphous interface layer in a similar manner to that described above. Monocrystalline semiconductor layer 26 is then formed (by epitaxial growth) overlying the monocrystalline accommodating buffer layer. The accommodating buffer layer is then exposed to an anneal process to convert the monocrystalline accommodating buffer layer to an amorphous layer. Amorphous layer 36 formed in this manner comprises materials from both the accommodating buffer and interface layers, which amorphous layers may or may not amalgamate. Thus, layer 36 may comprise one or two amorphous layers. Formation of amorphous layer 36 between substrate 22 and semiconductor layer 38 (subsequent to layer 38 formation) relieves stresses between layers 22 and 38 and provides a true compliant substrate for subsequent processing—e.g., compound semiconductor layer 26 formation.

The processes previously described above in connection with FIGS. 1 and 2 are adequate for growing monocrystalline compound semiconductor layers over a monocrystalline substrate. However, the process described in connection with FIG. 3, which includes transforming a monocrystalline accommodating buffer layer to an amorphous oxide layer, may be better for growing monocrystalline compound semiconductor layers because it allows any strain in layer 26 to relax.

Semiconductor layer 38 may include any of the materials described throughout this application in connection with either of compound semiconductor material layer 26 or additional buffer layer 32. For example, layer 38 may include monocrystalline Group IV or monocrystalline compound semiconductor materials.

In accordance with one embodiment of the present invention, semiconductor layer 38 serves as an anneal cap during layer 36 formation and as a template for subsequent semiconductor layer 26 formation. Accordingly, layer 38 is preferably thick enough to provide a suitable template for layer 26 growth (at least one monolayer) and thin enough to allow layer 38 to form as a substantially defect free monocrystalline semiconductor compound.

In accordance with another embodiment of the invention, semiconductor layer 38 comprises compound semiconductor material (e.g., a material discussed above in connection with compound semiconductor layer 26) that is thick enough to form devices within layer 38. In this case, a semiconductor structure in accordance with the present invention does not include compound semiconductor layer 26. In other words, the semiconductor structure in accordance with this embodiment only includes one compound semiconductor layer disposed above amorphous oxide layer 36.

The layer formed on substrate 22, whether it includes only accommodating buffer layer 24, accommodating buffer layer 24 with amorphous intermediate or interface layer 28, an amorphous layer such as layer 36 formed by annealing layers 24 and 28 as described above in connection with FIG. 3, or template layer 30, may be referred to generically as an “accommodating layer.”

The following non-limiting, illustrative examples illustrate various combinations of materials useful in structures 20, 40 and 34 in accordance with various alternative embodiments. These examples are merely illustrative, and it is not intended that the invention be limited to these illustrative examples.

### EXAMPLE 1

In accordance with one embodiment, monocrystalline substrate 22 is a silicon substrate oriented in the (100) direction. Silicon substrate 22 can be, for example, a silicon substrate as is commonly used in making complementary metal oxide semiconductor (CMOS) integrated circuits having a diameter of about 200-300 mm. In accordance with this embodiment, accommodating buffer layer 24 is a monocrystalline layer of Sr_{z}Ba_{1-z}TiO₃ where z ranges from 0 to 1 and amorphous intermediate layer 28 is a layer of silicon oxide (SiOₓ) formed at the interface between silicon substrate 22 and accommodating buffer layer 24. The value of z is selected to obtain one or more lattice constants closely matched to corresponding lattice constants of the subsequently formed layer 26. Accommodating buffer layer 24 can have a thickness of about 2 to about 100 nanometers (nm) and preferably has a thickness of about 5 nm. In general, it is desired to have an accommodating buffer layer 24 thick enough to isolate monocrystalline material layer 26 from substrate 22 to obtain the desired electrical and optical properties. Layers thicker than 100 nm usually provide little additional benefit while increasing cost unnecessarily; however, thicker layers may be fabricated if needed. The amorphous intermediate layer 28 of silicon oxide can have a thickness of about 0.5-5 nm, and preferably a thickness of about 1-2 nm.

In accordance with this embodiment, compound semiconductor material layer 26 is a layer of gallium arsenide (GaAs) or aluminum gallium arsenide (AlGaAs) having a thickness of about 1 nm to about 100 micrometers (μm) and preferably a thickness of about 0.5 μm to 10 μm. The thickness generally depends on the application for which the layer is being prepared. To facilitate the epitaxial growth of the gallium arsenide or aluminum gallium arsenide on the monocrystalline oxide, a template layer 30 is formed by capping the oxide layer. Template layer 30 is preferably 1-10 monolayers of Ti—As, Sr—O—As, Sr—Ga—O, or Sr—Al—O. By way of a preferred example, 1-2 monolayers 30 of Ti—As or Sr—Ga—O have been shown to successfully grow GaAs layers 26.

### EXAMPLE 2

In accordance with a further embodiment, monocrystalline substrate 22 is a silicon substrate as described above. Accommodating buffer layer 24 is a monocrystalline oxide of strontium or barium zirconate or hafnate in a cubic or orthorhombic phase with an amorphous intermediate layer 28 of silicon oxide formed at the interface between silicon substrate 22 and accommodating buffer layer 24. Accommodating buffer layer 24 can have a thickness of about 2-100 nm and preferably has a thickness of at least 5 nm to ensure adequate crystalline and surface quality and is formed of a monocrystalline SrZrO₃, BaZrO₃, SrHfO₃, BaSnO₃ or BaHfO₃. For example, a monocrystalline oxide layer of BaZrO₃ can grow at a temperature of about 700 degrees C. The lattice structure of the resulting crystalline oxide exhibits a 45 degree rotation with respect to the substrate 22 silicon lattice structure.

An accommodating buffer layer 24 formed of these zirconate or hafnate materials is suitable for the growth of compound semiconductor materials 26 in the indium phosphide (InP) system. The compound semiconductor material 26 can be, for example, indium phosphide (InP), indium gallium arsenide (InGaAs), aluminum indium arsenide, (AlInAs), or aluminum gallium indium arsenic phosphide (AlGaInAsP), having a thickness of about 1.0 nm to 10 μm. A suitable template 30 for this structure is 1-10 monolayers of zirconium-arsenic (Zr—As), zirconium-phosphorus (Zr—P), hafnium-arsenic (Hf—As), hafnium-phosphorus (Hf—P), strontium-oxygen-arsenic (Sr—O—As), strontium-oxygen-phosphorus (Sr—O—P), barium-oxygen-arsenic (Ba—O—As), indium-strontium-oxygen (In—Sr—O), or barium-oxygen-phosphorus (Ba—O—P), and preferably 1-2 monolayers of one of these materials. By way of an example, for a barium zirconate accommodating buffer layer 24, the surface is terminated with 1-2 monolayers of zirconium followed by deposition of 1-2 monolayers of arsenic to form a Zr—As template 30. A monocrystalline layer 26 of the compound semiconductor material from the indium phosphide system is then grown on template layer 30. The resulting lattice structure of the compound semiconductor material 26 exhibits a 45 degree rotation with respect to the accommodating buffer layer 24 lattice structure and a lattice mismatch to (100) InP of less than 2.5%, and preferably less than about 1.0%.

### EXAMPLE 3

In accordance with a further embodiment, a structure is provided that is suitable for the growth of an epitaxial film of a II-VI material overlying a silicon substrate 22. The substrate 22 is preferably a silicon wafer as described above. A suitable accommodating buffer layer 24 material is SrₓBa₁₋ₓTiO₃, where x ranges from 0 to 1, having a thickness of about 2-100 nm and preferably a thickness of about 5-15 nm. The II-VI compound semiconductor material 26 can be, for example, zinc selenide (ZnSe) or zinc sulfur selenide (ZnSSe). A suitable template 30 for this material system includes 1-10 monolayers of zinc-oxygen (Zn—O) followed by 1-2 monolayers of an excess of zinc followed by the selenidation of zinc on the surface. Alternatively, a template 30 can be, for example, 1-10 monolayers of strontium-sulfur (Sr—S) followed by the ZnSeS.

### EXAMPLE 4

This embodiment of the invention is an example of structure 40 illustrated in FIG. 2. Substrate 22, monocrystalline oxide layer 24, and monocrystalline compound semiconductor material layer 26 can be similar to those described in example 1. In addition, an additional buffer layer 32 serves to alleviate any strains that might result from a mismatch of the crystal lattice of the accommodating buffer layer and the lattice of the monocrystalline semiconductor material. The additional buffer layer 32 can be a layer of germanium or a GaAs, an aluminum gallium arsenide (AlGaAs), an indium gallium phosphide (InGaP), an aluminum gallium phosphide (AlGaP), an indium gallium arsenide (InGaAs), an aluminum indium phosphide (AlInP), a gallium arsenide phosphide (GaAsP), or an indium gallium phosphide (InGaP) strain compensated superlattice. In accordance with one aspect of this embodiment, buffer layer 32 includes a GaAsₓP₁₋ₓ superlattice, wherein the value of x ranges from 0 to 1. In accordance with another aspect, buffer layer 32 includes an In_{y}Ga_{1-y}P superlattice, wherein the value of y ranges from 0 to 1. By varying the value of x or y, as the case may be, the lattice constant is varied from bottom to top across the superlattice to create a match between lattice constants of the underlying oxide and the overlying compound semiconductor material. The compositions of other materials, such as those listed above, may also be similarly varied to manipulate the lattice constant of layer 32 in a like manner. The superlattice can have a thickness of about 50-500 nm and preferably has a thickness of about 100-200 nm. The template for this structure can be the same of that described in example 1. Alternatively, buffer layer 32 can be a layer of monocrystalline germanium having a thickness of 1-50 nm and preferably having a thickness of about 2-20 nm. In using a germanium buffer layer, a template layer of either germanium-strontium (Ge—Sr) or germanium-titanium (Ge—Ti) having a thickness of about one monolayer can be used as a nucleating site for the subsequent growth of the monocrystalline compound semiconductor material layer. The formation of the oxide layer is capped with either a monolayer of strontium or a monolayer of titanium to act as a nucleating site for the subsequent deposition of the monocrystalline germanium. The monolayer of strontium or titanium provides a nucleating site to which the first monolayer of germanium can bond.

### EXAMPLE 5

This example also illustrates materials useful in a structure 40 as illustrated in FIG. 2. Substrate material 22, accommodating buffer layer 24, monocrystalline compound semiconductor material layer 26 and template layer 30 can be the same as those described above in example 2. In addition, a buffer layer 32 is inserted between accommodating buffer layer 24 and overlying monocrystalline compound semiconductor material layer 26. Buffer layer 32, a further monocrystalline semiconductor material, can be, for example, a graded layer of indium gallium arsenide (InGaAs) or indium aluminum arsenide (InAlAs). In accordance with one aspect of this embodiment, buffer layer 32 includes InGaAs, in which the indium composition varies from 0 to about 50%. The additional buffer layer 32 preferably has a thickness of about 10-30 nm. Varying the composition of buffer layer 32 from GaAs to InGaAs serves to provide a lattice match between the underlying monocrystalline oxide material 24 and the overlying layer 26 of monocrystalline compound semiconductor material. Such a buffer layer 32 is especially advantageous if there is a lattice mismatch between accommodating buffer layer 24 and monocrystalline compound semiconductor material layer 26.

### EXAMPLE 6

This example provides exemplary materials useful in structure 34, as illustrated in FIG. 3. Substrate material 22, template layer 30, and monocrystalline compound semiconductor material layer 26 may be the same as those described above in connection with example 1.

Amorphous layer 36 is an amorphous oxide layer which is suitably formed of a combination of amorphous intermediate layer materials (e.g., layer 28 materials as described above) and accommodating buffer layer materials (e.g., layer 24 materials as described above). For example, amorphous layer 36 may include a combination of SiOₓ and Sr_{z}Ba_{1-z}TiO₃ (where z ranges from 0 to 1), which combine or mix, at least partially, during an anneal process to form amorphous oxide layer 36.

The thickness of amorphous layer 36 may vary from application to application and may depend on such factors as desired insulating properties of layer 36, type of semiconductor material comprising layer 26, and the like. In accordance with one exemplary aspect of the present embodiment, layer 36 thickness is about 2 nm to about 100 nm, preferably about 2-10 nm, and more preferably about 56 nm.

Layer 38 comprises a monocrystalline compound semiconductor material that can be grown epitaxially over a monocrystalline oxide material such as material used to form accommodating buffer layer 24. In accordance with one embodiment of the invention, layer 38 includes the same materials as those comprising layer 26. For example, if layer 26 includes GaAs, layer 38 also includes GaAs. However, in accordance with other embodiments of the present invention, layer 38 may include materials different from those used to form layer 26. In accordance with one exemplary embodiment of the invention, layer 38 is about 1 monolayer to about 100 nm thick.

Referring again to FIGS. 1-3, substrate 22 is a monocrystalline substrate such as a monocrystalline silicon substrate. The crystalline structure of the monocrystalline substrate is characterized by a lattice constant and by a lattice orientation. In similar manner, accommodating buffer layer 24 is also a monocrystalline material and the lattice of that monocrystalline material is characterized by a lattice constant and a crystal orientation. The lattice constants of accommodating buffer layer 24 and monocrystalline substrate 22 must be closely matched or, alternatively, must be such that upon rotation of one crystal orientation with respect to the other crystal orientation, a substantial match in lattice constants is achieved. In this context the terms “substantially equal” and “substantially matched” mean that there is sufficient similarity between the lattice constants to permit the growth of a high quality crystalline layer on the underlying layer.

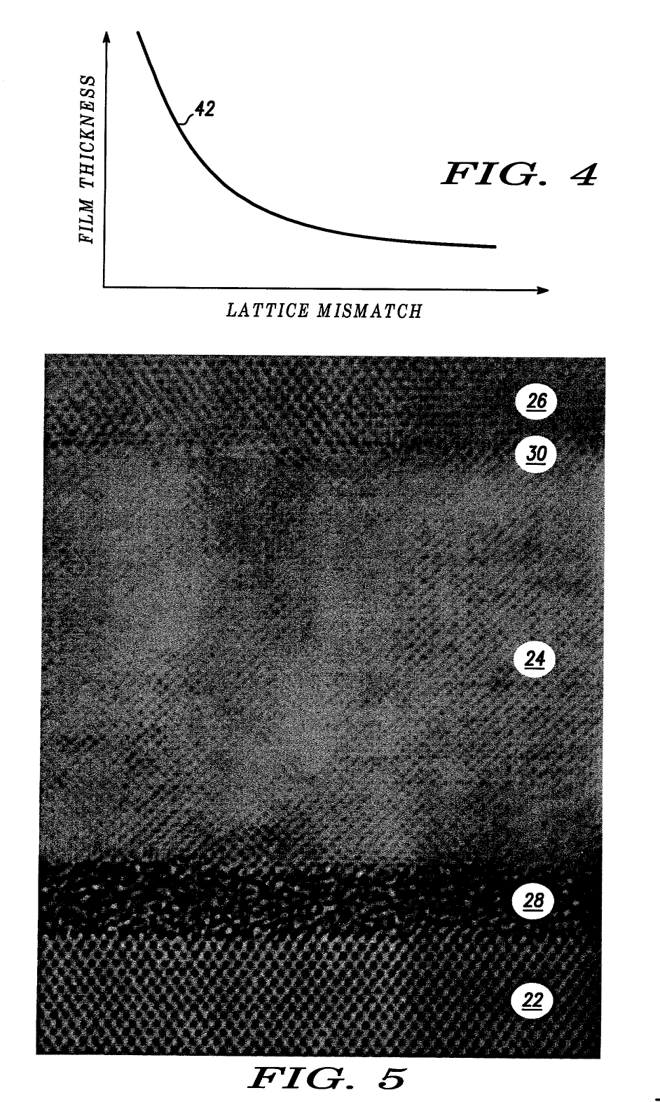

FIG. 4 illustrates graphically the relationship of the achievable thickness of a grown crystal layer of high crystalline quality as a function of the mismatch between the lattice constants of the host crystal and the grown crystal. Curve 42 illustrates the boundary of high crystalline quality material. The area to the right of curve 42 represents layers that tend to be polycrystalline. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved.

In accordance with one embodiment, substrate 22 is a (100) or (111) oriented monocrystalline silicon wafer and accommodating buffer layer 24 is a layer of strontium barium titanate. Substantial matching of lattice constants between these two materials is achieved by rotating the crystal orientation of the titanate material 24 by 45E with respect to the crystal orientation of the silicon substrate wafer 22. The inclusion in the structure of amorphous interface layer 28, a silicon oxide layer in this example, if it is of sufficient thickness, serves to reduce strain in the titanate monocrystalline layer 24 that might result from any mismatch in the lattice constants of the host silicon wafer 22 and the grown titanate layer 24. As a result, a high quality, thick, monocrystalline titanate layer 24 is achievable.

Still referring to FIGS. 1-3, layer 26 is a layer of epitaxially grown monocrystalline material and that crystalline material is also characterized by a crystal lattice constant and a crystal orientation. In accordance with one embodiment of the invention, the lattice constant of layer 26 differs from the lattice constant of substrate 22. To achieve high crystalline quality in this epitaxially grown monocrystalline layer, accommodating buffer layer 24 must be of high crystalline quality. In addition, in order to achieve high crystalline quality in layer 26, substantial matching between the crystal lattice constant of the host crystal, in this case, monocrystalline accommodating buffer layer 24, and grown crystal 26 is desired. With properly selected materials this substantial matching of lattice constants is achieved as a result of rotation of the crystal orientation of grown crystal 26 with respect to the orientation of host crystal 24. If grown crystal 26 is gallium arsenide, aluminum gallium arsenide, zinc selenide, or zinc sulfur selenide and accommodating buffer layer 24 is monocrystalline SrₓBa₁₋ₓTiO₃, substantial matching of crystal lattice constants of the two materials is achieved, wherein the crystal orientation of grown layer 26 is rotated by 45E with respect to the orientation of the host monocrystalline oxide 24. Similarly, if host material 24 is a strontium or barium zirconate or a strontium or barium hafnate or barium tin oxide and compound semiconductor layer 26 is indium phosphide or gallium indium arsenide or aluminum indium arsenide, substantial matching of crystal lattice constants can be achieved by rotating the orientation of grown crystal layer 26 by 45E with respect to host oxide crystal 24. In some instances, a crystalline semiconductor buffer layer 32 between host oxide 24 and grown compound semiconductor layer 26 can be used to reduce strain in grown monocrystalline compound semiconductor layer 26 that might result from small differences in lattice constants. Better crystalline quality in grown monocrystalline compound semiconductor layer 26 can thereby be achieved.

The following example illustrates a process, in accordance with one embodiment, for fabricating a semiconductor structure such as the structures depicted in FIGS. 1-3. The process starts by providing a monocrystalline semiconductor substrate 22 comprising silicon or germanium. In accordance with a preferred embodiment, semiconductor substrate 22 is a silicon wafer having a (100) orientation. Substrate 22 is preferably oriented on axis or, at most, about 4° off axis. At least a portion of semiconductor substrate 22 has a bare surface, although other portions of the substrate, as described below, may encompass other structures. The term “bare” in this context means that the surface in the portion of substrate 22 has been cleaned to remove any oxides, contaminants, or other foreign material. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process. In order to epitaxially grow a monocrystalline oxide layer 24 overlying monocrystalline substrate 22, the native oxide layer must first be removed to expose the crystalline structure of underlying substrate 22. The following process is preferably carried out by molecular beam epitaxy (MBE), although other epitaxial processes may also be used in accordance with the present invention. The native oxide can be removed by first thermally depositing a thin layer of strontium, barium, a combination of strontium and barium, or other alkaline earth metals or combinations of alkaline earth metals in an MBE apparatus. In the case where strontium is used, the substrate 22 is then heated to a temperature of about 750° C. to cause the strontium to react with the native silicon oxide layer. The strontium serves to reduce the silicon oxide to leave a silicon oxide-free surface. The resultant surface, which exhibits an ordered 2×1 structure, includes strontium, oxygen, and silicon. The ordered 2×1 structure forms a template for the ordered growth of an overlying layer 24 of a monocrystalline oxide. The template provides the necessary chemical and physical properties to nucleate the crystalline growth of an overlying layer 24.

In accordance with an alternate embodiment, the native silicon oxide can be converted and the surface of substrate 22 can be prepared for the growth of a monocrystalline oxide layer 24 by depositing an alkaline earth metal oxide, such as strontium oxide or barium oxide, onto the substrate surface by MBE at a low temperature and by subsequently heating the structure to a temperature of about 750° C. At this temperature a solid state reaction takes place between the strontium oxide and the native silicon oxide causing the reduction of the native silicon oxide and leaving an ordered 2×1 structure with strontium, oxygen, and silicon remaining on the substrate 22 surface. Again, this forms a template for the subsequent growth of an ordered monocrystalline oxide layer 24.

Following the removal of the silicon oxide from the surface of substrate 22, the substrate is cooled to a temperature in the range of about 200-800 EC and a layer 24 of strontium titanate is grown on the template layer by molecular beam epitaxy. The MBE process is initiated by opening shutters in the MBE apparatus to expose strontium, titanium and oxygen sources. The ratio of strontium and titanium is approximately 1:1. The partial pressure of oxygen is initially set at a minimum value to grow stoichiometric strontium titanate at a growth rate of about 0.3-0.5 nm per minute. After initiating growth of the strontium titanate, the partial pressure of oxygen is increased above the initial minimum value. The overpressure of oxygen causes the growth of an amorphous silicon oxide layer 28 at the interface between underlying substrate 22 and the growing strontium titanate layer 24. The growth of silicon oxide layer 28 results from the diffusion of oxygen through the growing strontium titanate layer 24 to the interface where the oxygen reacts with silicon at the surface of underlying substrate 22. The strontium titanate grows as an ordered (100) monocrystal 24 with the (100) crystalline orientation rotated by 45° with respect to the underlying substrate 22. Strain that otherwise might exist in strontium titanate layer 24 because of the small mismatch in lattice constant between silicon substrate 22 and the growing crystal 24 is relieved in amorphous silicon oxide intermediate layer 28.

After strontium titanate layer 24 has been grown to the desired thickness, the monocrystalline strontium titanate is capped by a template layer 30 that is conducive to the subsequent growth of an epitaxial layer of a desired compound semiconductor material 26. For the subsequent growth of a layer 26 of gallium arsenide, the MBE growth of strontium titanate monocrystalline layer 24 can be capped by terminating the growth with 1-2 monolayers of titanium, 1-2 monolayers of titanium-oxygen or with 1-2 monolayers of strontium-oxygen. Following the formation of this capping layer, arsenic is deposited to form a Ti—As bond, a Ti—O—As bond or a Sr—O—As. Any of these form an appropriate template 30 for deposition and formation of a gallium arsenide monocrystalline layer 26. Following the formation of template 30, gallium is subsequently introduced to the reaction with the arsenic and gallium arsenide 26 forms. Alternatively, gallium can be deposited on the capping layer to form a Sr—O—Ga bond, and arsenic is subsequently introduced with the gallium to form the GaAs.

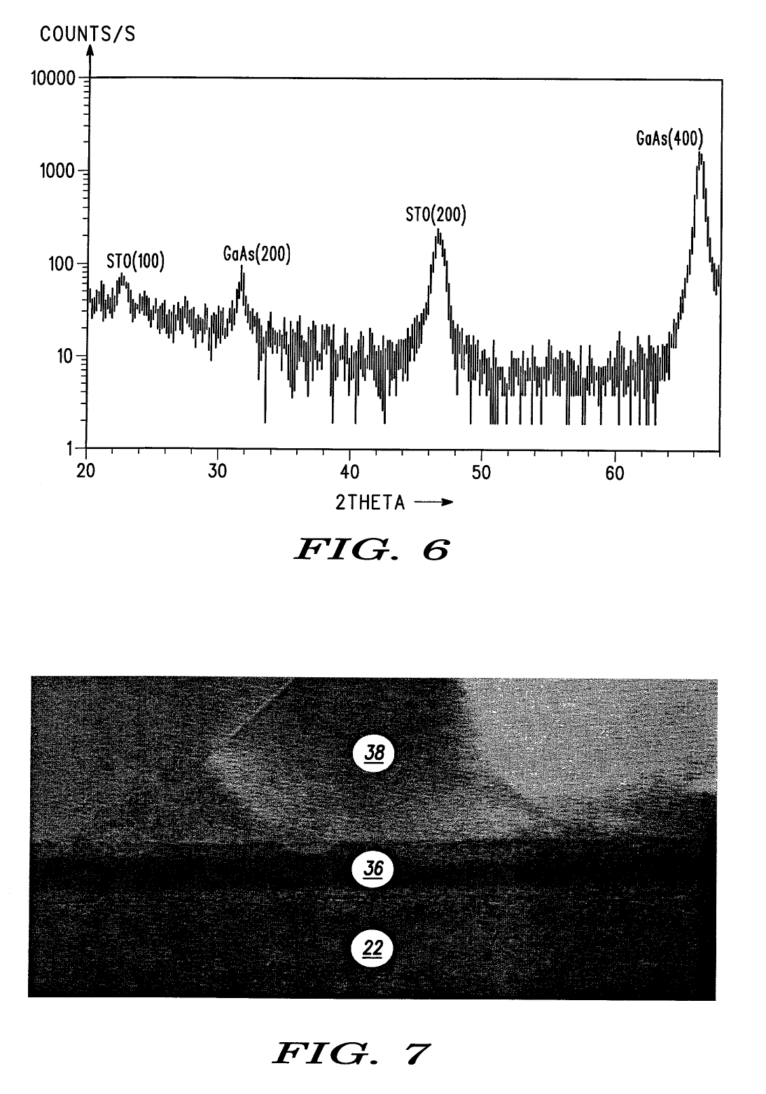

FIG. 5 is a high resolution Transmission Electron Micrograph (TEM) of semiconductor material manufactured in accordance with the present invention. Single crystal SrTiO3 accommodating buffer layer 24 was grown epitaxially on silicon substrate 22. During this growth process, amorphous interfacial layer 28 is formed which relieves strain due to lattice mismatch. GaAs compound semiconductor layer 26 was then grown epitaxially using template layer 30.

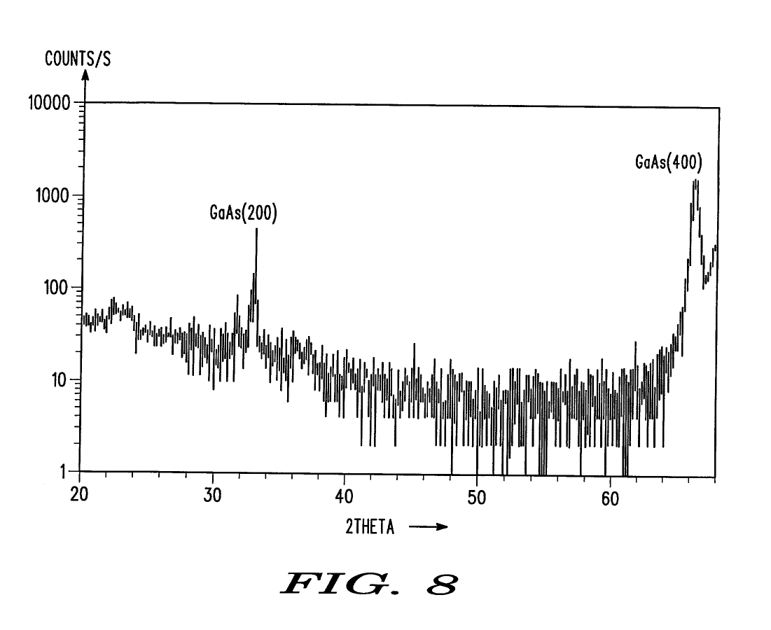

FIG. 6 illustrates an x-ray diffraction spectrum taken on a structure including GaAs compound semiconductor layer 26 grown on silicon substrate 22 using accommodating buffer layer 24. The peaks in the spectrum indicate that both the accommodating buffer layer 24 and GaAs compound semiconductor layer 26 are single crystal and (100) orientated.

The structure illustrated in FIG. 2 can be formed by the process discussed above with the addition of an additional buffer layer 32 deposition step. The additional buffer layer 32 is formed overlying template layer 30 before the deposition of monocrystalline compound semiconductor layer 26. If additional buffer layer 32 is a compound semiconductor superlattice, such a superlattice can be deposited, by MBE for example, on the template 30 described above. If instead additional buffer layer 32 is a layer of germanium, the process above is modified to cap strontium titanate monocrystalline layer 24 with a final layer of either strontium or titanium and then by depositing germanium to react with the strontium or titanium. The germanium buffer layer 32 can then be deposited directly on this template 30.

Structure 34, illustrated in FIG. 3, may be formed by growing an accommodating buffer layer, forming an amorphous oxide layer over substrate 22, and growing semiconductor layer 38 over the accommodating buffer layer, as described above. The accommodating buffer layer and the amorphous oxide layer are then exposed to an anneal process sufficient to change the crystalline structure of the accommodating buffer layer from monocrystalline to amorphous, thereby forming an amorphous layer such that the combination of the amorphous oxide layer and the now amorphous accommodating buffer layer form a single amorphous oxide layer 36. Layer 26 is then subsequently grown over layer 38. Alternatively, the anneal process may be carried out subsequent to growth of layer 26.

In accordance with one aspect of this embodiment, layer 36 is formed by exposing substrate 22, the accommodating buffer layer, the amorphous oxide layer, and semiconductor layer 38 to a rapid thermal anneal process with a peak temperature of about 700 EC to about 1000 EC and a process time of about 5 seconds to about 10 minutes. However, other suitable anneal processes may be employed to convert the accommodating buffer layer to an amorphous layer in accordance with the present invention. For example, laser annealing or “conventional” thermal annealing processes (in the proper environment) may be used to form layer 36. When conventional thermal annealing is employed to form layer 36, an overpressure of one or more constituents of layer 30 may be required to prevent degradation of layer 38 during the anneal process. For example, when layer 38 includes GaAs, the anneal environment preferably includes an overpressure of arsenic to mitigate degradation of layer 38.

As noted above, layer 38 of structure 34 may include any materials suitable for either of layers 32 or 26. Accordingly, any deposition or growth methods described in connection with either layer 32 or 26, may be employed to deposit layer 38.

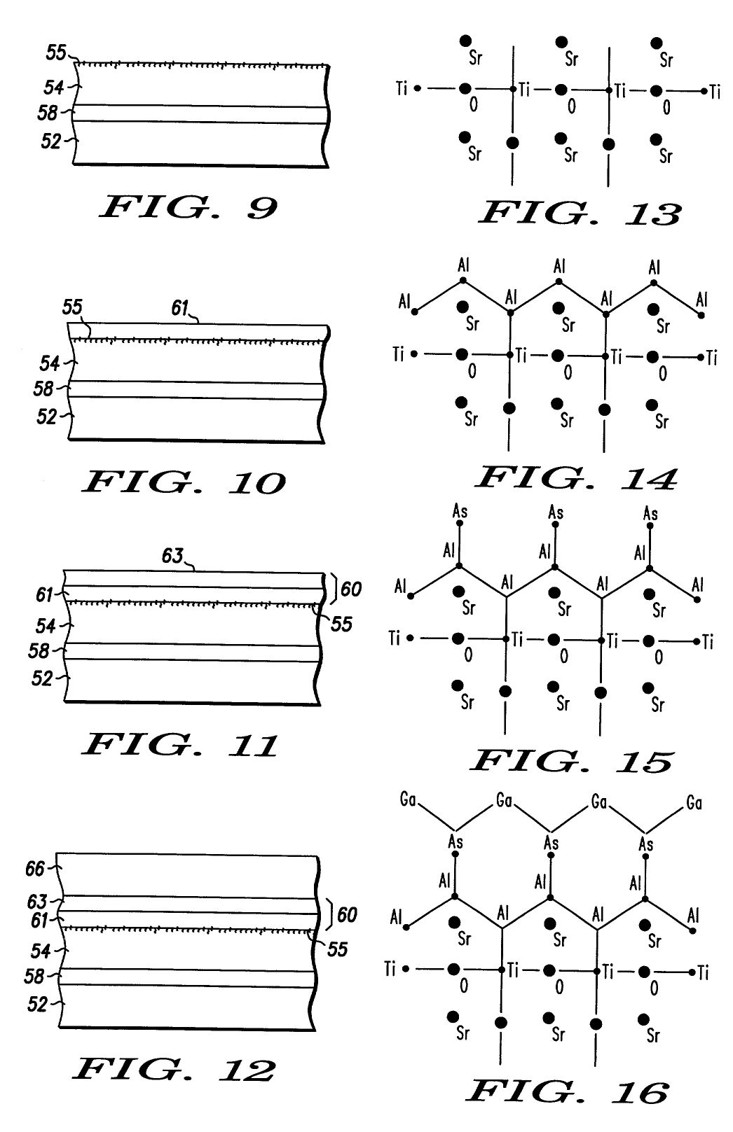

FIG. 7 is a high resolution Transmission Electron Micrograph (TEM) of semiconductor material manufactured in accordance with the embodiment of the invention illustrated in FIG. 3. In accordance with this embodiment, a single crystal SrTiO3 accommodating buffer layer was grown epitaxially on silicon substrate 22. During this growth process, an amorphous interfacial layer forms as described above. Next, GaAs layer 38 is formed above the accommodating buffer layer and the accommodating buffer layer is exposed to an anneal process to form amorphous oxide layer 36.

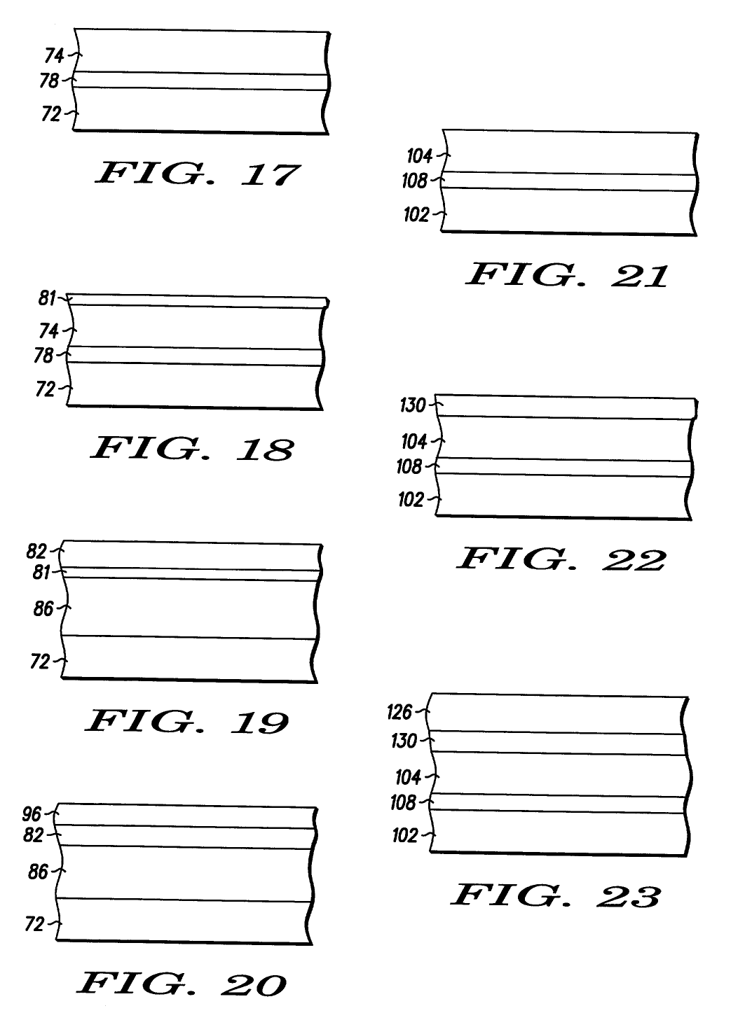

FIG. 8 illustrates an x-ray diffraction spectrum taken on a structure including GaAs compound semiconductor layer 38 and amorphous oxide layer 36 formed on silicon substrate 22. The peaks in the spectrum indicate that GaAs compound semiconductor layer 38 is single crystal and (100) orientated and the lack of peaks around 40 to 50 degrees indicates that layer 36 is amorphous.

The process described above illustrates a process for forming a semiconductor structure including a silicon substrate 22, an overlying oxide layer, and a monocrystalline gallium arsenide compound semiconductor layer 26 by the process of molecular beam epitaxy. The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Further, by a similar process, other monocrystalline accommodating buffer layers 24 such as alkaline earth metal titanates, zirconates, hafnates, tantalates, vanadates, ruthenates, and niobates, alkaline earth metal tin-based perovskites, lanthanum aluminate, lanthanum scandium oxide, and gadolinium oxide can also be grown. Further, by a similar process such as MBE, other III-V and II-VI monocrystalline compound semiconductor layers 26 can be deposited overlying monocrystalline oxide accommodating buffer layer 24.

Each of the variations of compound semiconductor materials 26 and monocrystalline oxide accommodating buffer layer 24 uses an appropriate template 30 for initiating the growth of the compound semiconductor layer. For example, if accommodating buffer layer 24 is an alkaline earth metal zirconate, the oxide can be capped by a thin layer of zirconium. The deposition of zirconium can be followed by the deposition of arsenic or phosphorus to react with the zirconium as a precursor to depositing indium gallium arsenide, indium aluminum arsenide, or indium phosphide respectively. Similarly, if monocrystalline oxide accommodating buffer layer 24 is an alkaline earth metal hafnate, the oxide layer can be capped by a thin layer of hafnium. The deposition of hafnium is followed by the deposition of arsenic or phosphorous to react with the hafnium as a precursor to the growth of an indium gallium arsenide, indium aluminum arsenide, or indium phosphide layer 26, respectively. In a similar manner, strontium titanate 24 can be capped with a layer of strontium or strontium and oxygen, and barium titanate 24 can be capped with a layer of barium or barium and oxygen. Each of these depositions can be followed by the deposition of arsenic or phosphorus to react with the capping material to form a template 30 for the deposition of a compound semiconductor material layer 26 comprising indium gallium arsenide, indium aluminum arsenide, or indium phosphide.

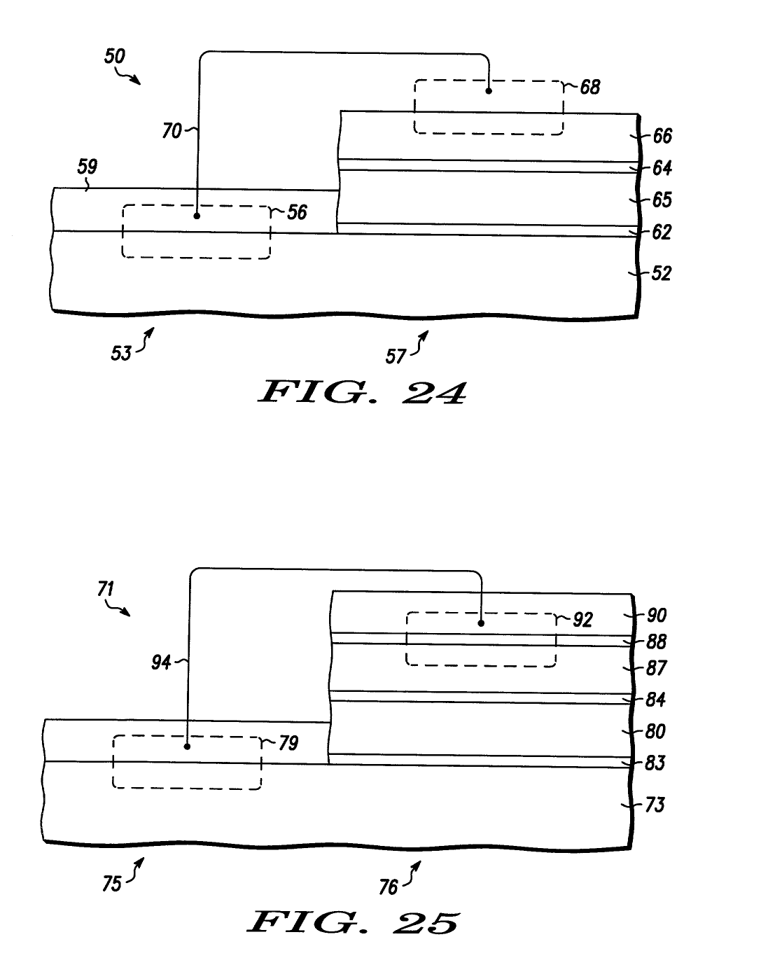

The formation of a device structure in accordance with another embodiment of the invention is illustrated schematically in cross-section in FIGS. 9-12. Like the previously described embodiments referred to in FIGS. 1-3, this embodiment of the invention involves the process of forming a compliant substrate utilizing the epitaxial growth of single crystal oxides, such as the formation of accommodating buffer layer 24 previously described with reference to FIGS. 1 and 2 and amorphous layer 36 previously described with reference to FIG. 3, and the formation of a template layer 30. However, the embodiment illustrated in FIGS. 9-12 utilizes a template that includes a surfactant to facilitate layer-by-layer monocrystalline material growth.

Turning now to FIG. 9, an amorphous intermediate layer 58 is grown on substrate 52 at the interface between substrate 52 and a growing accommodating buffer layer 54, which is preferably a monocrystalline crystal oxide layer, by the oxidation of substrate 52 during the growth of layer 54. Layer 54 is preferably a monocrystalline oxide material such as a monocrystalline layer of SrZBa1-ZTiO3 where z ranges from 0 to 1. However, layer 54 may also comprise any of those compounds previously described with reference to layer 24 in FIGS. 1-2 and any of those compounds previously described with reference to layer 36 in FIG. 3 which is formed from layers 24 and 28 referenced in FIGS. 1 and 2.

Layer 54 is grown with a strontium (Sr) terminated surface represented in FIG. 9 by hatched line 55 which is followed by the addition of a template layer 60 which includes a surfactant layer 61 and capping layer 63 as illustrated in FIGS. 10 and 11. Surfactant layer 61 may comprise, but is not limited to, elements such as Al, In and Ga, but will be dependent upon the composition of layer 54 and the overlying layer of monocrystalline material for optimal results. In one exemplary embodiment, aluminum (Al) is used for surfactant layer 61 and functions to modify the surface and surface energy of layer 54. Preferably, surfactant layer 61 is epitaxially grown, to a thickness of one to two monolayers, over layer 54 as illustrated in FIG. 10 by way of molecular beam epitaxy (MBE), although other epitaxial processes may also be performed including chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like.

Surfactant layer 61 is then exposed to a Group V element such as arsenic, for example, to form capping layer 63 as illustrated in FIG. 11. Surfactant layer 61 may be exposed to a number of materials to create capping layer 63 such as elements which include, but are not limited to, As, P, Sb and N. Surfactant layer 61 and capping layer 63 combine to form template layer 60.

Monocrystalline material layer 66, which in this example is a compound semiconductor such as GaAs, is then deposited via MBE, CVD, MOCVD, MEE, ALE, PVD, CSD, PLD, or the like to form the final structure illustrated in FIG. 12.

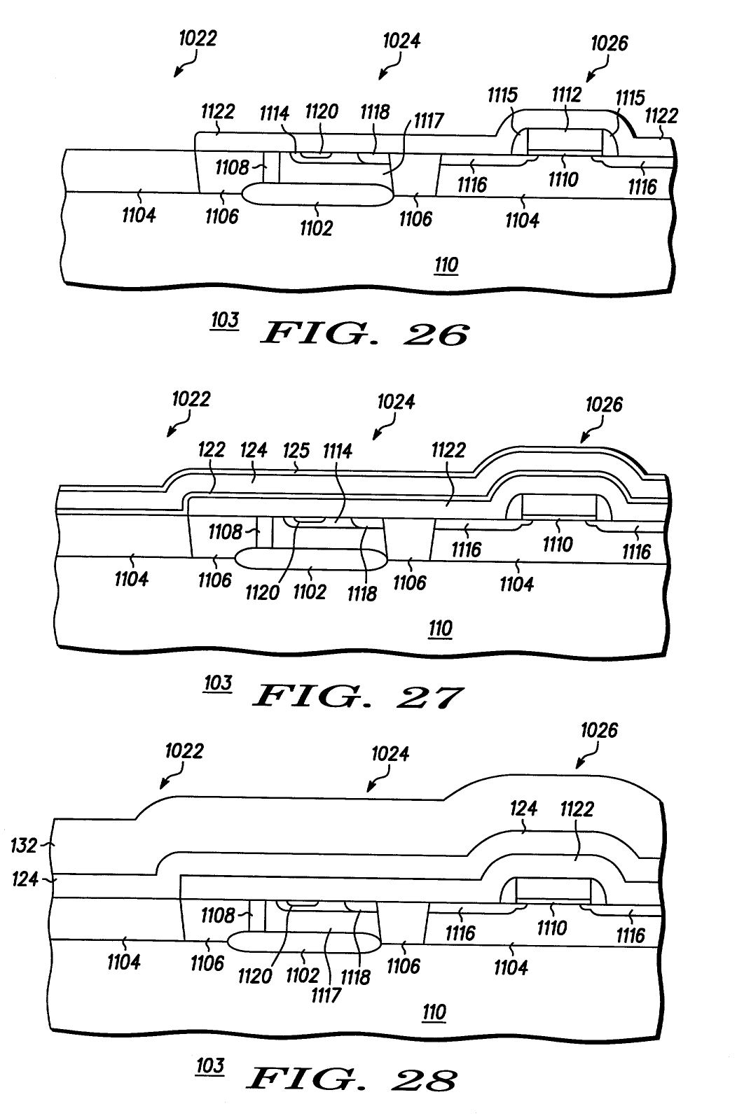

FIGS. 13-16 illustrate possible molecular bond structures for a specific example of a compound semiconductor structure formed in accordance with the embodiment of the invention illustrated in FIGS. 9-12. More specifically, FIGS. 13-16 illustrate the growth of GaAs (layer 66) on the strontium terminated surface of a strontium titanate monocrystalline oxide (layer 54) using a surfactant containing template (layer 60).

The growth of a monocrystalline material layer 66 such as GaAs on an accommodating buffer layer 54 such as a strontium titanium oxide over amorphous interface layer 58 and substrate layer 52, both of which may comprise materials previously described with reference to layers 28 and 22, respectively in FIGS. 1 and 2, illustrates a critical thickness of about 1000 Angstroms where the two-dimensional (2D) and three-dimensional (3D) growth shifts because of the surface energies involved. In order to maintain a true layer by layer growth (Frank Van der Mere growth), the following relationship must be satisfied:

δ_{STO}>(δ_{INT}+δ_{GaAS})

where the surface energy of the monocrystalline oxide layer 54 must be greater than the surface energy of the amorphous interface layer 58 added to the surface energy of the GaAs layer 66. Since it is impracticable to satisfy this equation, a surfactant containing template was used, as described above with reference to FIGS. 10-12, to increase the surface energy of the monocrystalline oxide layer 54 and also to shift the crystalline structure of the template to a diamond-like structure that is in compliance with the original GaAs layer.

FIG. 13 illustrates the molecular bond structure of a strontium terminated surface of a strontium titanate monocrystalline oxide layer. An aluminum surfactant layer is deposited on top of the strontium terminated surface and bonds with that surface as illustrated in FIG. 14, which reacts to form a capping layer comprising a monolayer of Al₂Sr having the molecular bond structure illustrated in FIG. 14 which forms a diamond-like structure with an sp³ hybrid terminated surface that is compliant with compound semiconductors such as GaAs. The structure is then exposed to As to form a layer of AlAs as shown in FIG. 15. GaAs is then deposited to complete the molecular bond structure illustrated in FIG. 16 which has been obtained by 2D growth. The GaAs can be grown to any thickness for forming other semiconductor structures, devices, or integrated circuits. Alkaline earth metals such as those in Group IIA are those elements preferably used to form the capping surface of the monocrystalline oxide layer 54 because they are capable of forming a desired molecular structure with aluminum.

In this embodiment, a surfactant containing template layer aids in the formation of a compliant substrate for the monolithic integration of various material layers including those comprised of Group III-V compounds to form high quality semiconductor structures, devices and integrated circuits. For example, a surfactant containing template may be used for the monolithic integration of a monocrystalline material layer such as a layer comprising Germanium (Ge), for example, to form high efficiency photocells.

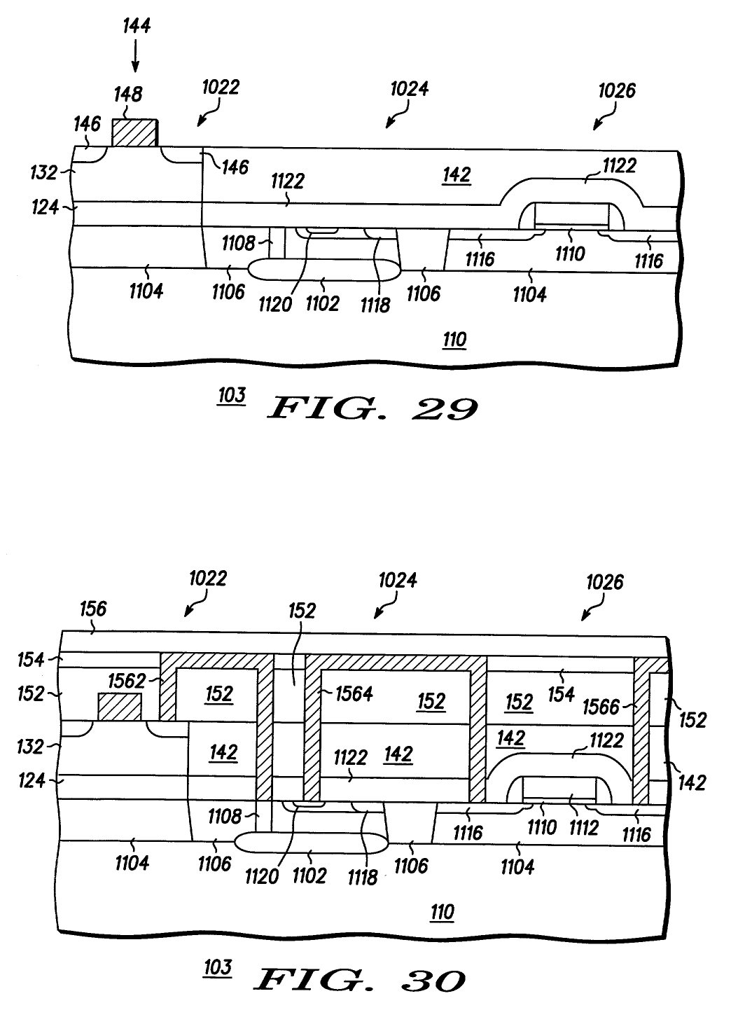

Turning now to FIGS. 17-20, the formation of a device structure in accordance with still another embodiment of the invention is illustrated in cross-section. This embodiment utilizes the formation of a compliant substrate which relies on the epitaxial growth of single crystal oxides on silicon followed by the epitaxial growth of single crystal silicon onto the oxide.

An accommodating buffer layer 74 such as a monocrystalline oxide layer is first grown on a substrate layer 72, such as silicon, with an amorphous interface layer 78 as illustrated in FIG. 17. Monocrystalline oxide layer 74 may be comprised of any of those materials previously discussed with reference to layer 24 in FIGS. 1 and 2, while amorphous interface layer 78 is preferably comprised of any of those materials previously described with reference to the layer 28 illustrated in FIGS. 1 and 2. Substrate 72, although preferably silicon, may also comprise any of those materials previously described with reference to substrate 22 in FIGS. 1-3.

Next, a silicon layer 81 is deposited over monocrystalline oxide layer 74 via MBE, CVD, MOCVD, MEE, ALE, PVD, CSD, PLD, and the like as illustrated in FIG. 18 with a thickness of a few hundred Angstroms but preferably with a thickness of about 50 Angstroms. Monocrystalline oxide layer 74 preferably has a thickness of about 20 to 100 Angstroms.

Rapid thermal annealing is then conducted in the presence of a carbon source such as acetylene or methane, for example at a temperature within a range of about 800° C. to 1000° C. to form capping layer 82 and silicate amorphous layer 86. However, other suitable carbon sources may be used as long as the rapid thermal annealing step functions to amorphize the monocrystalline oxide layer 74 into a silicate amorphous layer 86 and carbonize the top silicon layer 81 to form capping layer 82 which in this example would be a silicon carbide (SiC) layer as illustrated in FIG. 19. The formation of amorphous layer 86 is similar to the formation of layer 36 illustrated in FIG. 3 and may comprise any of those materials described with reference to layer 36 in FIG. 3 but the preferable material will be dependent upon the capping layer 82 used for silicon layer 81.

Finally, a compound semiconductor layer 96, shown in FIG. 20, such as gallium nitride (GaN) is grown over the SiC surface by way of MBE, CVD, MOCVD, MEE, ALE, PVD, CSD, PLD, or the like to form a high quality compound semiconductor material for device formation. More specifically, the deposition of GaN and GaN based systems such as GaInN and AlGaN will result in the formation of dislocation nets confined at the silicon/amorphous region. The resulting nitride containing compound semiconductor material may comprise elements from groups III, IV and V of the periodic table and is defect free.

Although GaN has been grown on SiC substrate in the past, this embodiment of the invention possesses a one step formation of the compliant substrate containing a SiC top surface and an amorphous layer on a Si surface. More specifically, this embodiment of the invention uses an intermediate single crystal oxide layer that is amorphized to form a silicate layer which adsorbs the strain between the layers. Moreover, unlike past use of a SiC substrate, this embodiment of the invention is not limited by wafer size which is usually less than 50 mm in diameter for prior art SiC substrates.

The monolithic integration of nitride containing semiconductor compounds containing group III-V nitrides and silicon devices can be used for high temperature RF applications and optoelectronics. GaN systems have particular use in the photonic industry for the blue/green and UV light sources and detection. High brightness light emitting diodes (LEDs) and lasers may also be formed within the GaN system.

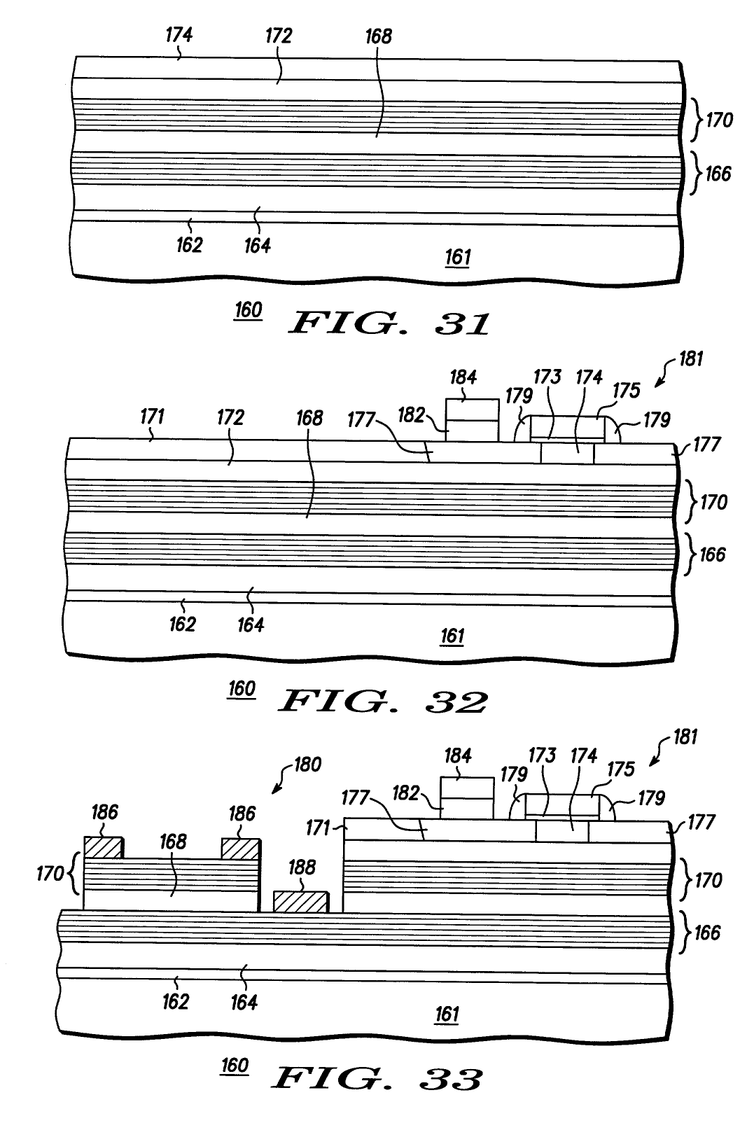

FIGS. 21-23 schematically illustrate, in cross-section, the formation of another embodiment of a device structure in accordance with the invention. This embodiment includes a compliant layer that functions as a transition layer that uses clathrate or Zintl type bonding. More specifically, this embodiment utilizes an intermetallic template layer to reduce the surface energy of the interface between material layers thereby allowing for two dimensional layer by layer growth.

The structure illustrated in FIG. 21 includes a monocrystalline substrate 102, an amorphous interface layer 108 and an accommodating buffer layer 104. Amorphous interface layer 108 is formed on substrate 102 at the interface between substrate 102 and accommodating buffer layer 104 as previously described with reference to FIGS. 1 and 2. Amorphous interface layer 108 may comprise any of those materials previously described with reference to amorphous interface layer 28 in FIGS. 1 and 2. Substrate 102 is preferably silicon but may also comprise any of those materials previously described with reference to substrate 22 in FIGS. 1-3.

A template layer 130 is deposited over accommodating buffer layer 104 as illustrated in FIG. 22 and preferably comprises a thin layer of Zintl type phase material composed of metals and metalloids having a great deal of ionic character. As in previously described embodiments, template layer 130 is deposited by way of MBE, CVD, MOCVD, MEE, ALE, PVD, CSD, PLD, or the like to achieve a thickness of one monolayer. Template layer 130 functions as a “soft” layer with non-directional bonding but high crystallinity which absorbs stress build up between layers having lattice mismatch. Materials for template 130 may include, but are not limited to, materials containing Si, Ga, In, and Sb such as, for example, AlSr₂, (MgCaYb)Ga₂, (Ca,Sr,Eu,Yb)In₂, BaGe₂As, and SrSn₂As₂.

A monocrystalline material layer 126 is epitaxially grown over template layer 130 to achieve the final structure illustrated in FIG. 23. As a specific example, an SrAl₂ layer may be used as template layer 130 and an appropriate monocrystalline material layer 126 such as a compound semiconductor material GaAs is grown over the SrAl₂. The Al—Ti (from the accommodating buffer layer of layer of Sr_{z}Ba_{1-z}TiO₃ where z ranges from 0 to 1) bond is mostly metallic while the Al—As (from the GaAs layer) bond is weakly covalent. The Sr participates in two distinct types of bonding with part of its electric charge going to the oxygen atoms in the lower accommodating buffer layer 104 comprising Sr_{z}Ba_{1-z}TiO₃ to participate in ionic bonding and the other part of its valence charge being donated to Al in a way that is typically carried out with Zintl phase materials. The amount of the charge transfer depends on the relative electronegativity of elements comprising the template layer 130 as well as on the interatomic distance. In this example, Al assumes an sp³ hybridization and can readily form bonds with monocrystalline material layer 126, which in this example, comprises compound semiconductor material GaAs.

The compliant substrate produced by use of the Zintl type template layer used in this embodiment can absorb a large strain without a significant energy cost. In the above example, the bond strength of the Al is adjusted by changing the volume of the SrAl₂ layer thereby making the device tunable for specific applications which include the monolithic integration of III-V and Si devices and the monolithic integration of high-k dielectric materials for CMOS technology.

Clearly, those embodiments specifically describing structures having compound semiconductor portions and Group IV semiconductor portions, are meant to illustrate embodiments of the present invention and not limit the present invention. There are a multiplicity of other combinations and other embodiments of the present invention. For example, the present invention includes structures and methods for fabricating material layers which form semiconductor structures, devices and integrated circuits including other layers such as metal and nonmetal layers. More specifically, the invention includes structures and methods for forming a compliant substrate which is used in the fabrication of semiconductor structures, devices and integrated circuits and the material layers suitable for fabricating those structures, devices, and integrated circuits. By using embodiments of the present invention, it is now simpler to integrate devices that include monocrystalline layers comprising semiconductor and compound semiconductor materials as well as other material layers that are used to form those devices with other components that work better or are easily and/or inexpensively formed within semiconductor or compound semiconductor materials. This allows a device to be shrunk, the manufacturing costs to decrease, and yield and reliability to increase.

In accordance with one embodiment of this invention, a monocrystalline semiconductor or compound semiconductor wafer can be used in forming monocrystalline material layers over the wafer. In this manner, the wafer is essentially a “handle” wafer used during the fabrication of semiconductor electrical components within a monocrystalline layer overlying the wafer. Therefore, electrical components can be formed within semiconductor materials over a wafer of at least approximately 200 millimeters in diameter and possibly at least approximately 300 millimeters.

By the use of this type of substrate, a relatively inexpensive “handle” wafer overcomes the fragile nature of compound semiconductor or other monocrystalline material wafers by placing them over a relatively more durable and easy to fabricate base material. Therefore, an integrated circuit can be formed such that all electrical components, and particularly all active electronic devices, can be formed within or using the monocrystalline material layer even though the substrate itself may include a monocrystalline semiconductor material. Fabrication costs for compound semiconductor devices and other devices employing non-silicon monocrystalline materials should decrease because larger substrates can be processed more economically and more readily compared to the relatively smaller and more fragile substrates (e.g. conventional compound semiconductor wafers).

FIG. 24 illustrates schematically, in cross section, a device structure 50 in accordance with a further embodiment. Device structure 50 includes a monocrystalline semiconductor substrate 52, preferably a monocrystalline silicon wafer. Monocrystalline semiconductor substrate 52 includes two regions, 53 and 57. An electrical semiconductor component generally indicated by the dashed line 56 is formed, at least partially, in region 53. Electrical component 56 can be a resistor, a capacitor, an active semiconductor component such as a diode or a transistor or an integrated circuit such as a CMOS integrated circuit. For example, electrical semiconductor component 56 can be a CMOS integrated circuit configured to perform digital signal processing or another function for which silicon integrated circuits are well suited. The electrical semiconductor component in region 53 can be formed by conventional semiconductor processing as well known and widely practiced in the semiconductor industry. A layer of insulating material 59 such as a layer of silicon dioxide or the like may overlie electrical semiconductor component 56.

Insulating material 59 and any other layers that may have been formed or deposited during the processing of semiconductor component 56 in region 53 are removed from the surface of region 57 to provide a bare silicon surface in that region. As is well known, bare silicon surfaces are highly reactive and a native silicon oxide layer can quickly form on the bare surface. A layer of barium or barium and oxygen is deposited onto the native oxide layer on the surface of region 57 and is reacted with the oxidized surface to form a first template layer (not shown). In accordance with one embodiment, a monocrystalline oxide layer is formed overlying the template layer by a process of molecular beam epitaxy. Reactants including barium, titanium and oxygen are deposited onto the template layer to form the monocrystalline oxide layer. Initially during the deposition the partial pressure of oxygen is kept near the minimum necessary to fully react with the barium and titanium to form monocrystalline barium titanate layer. The partial pressure of oxygen is then increased to provide an overpressure of oxygen and to allow oxygen to diffuse through the growing monocrystalline oxide layer. The oxygen diffusing through the barium titanate reacts with silicon at the surface of region 57 to form an amorphous layer of silicon oxide 62 on second region 57 and at the interface between silicon substrate 52 and the monocrystalline oxide layer 65. Layers 65 and 62 may be subject to an annealing process as described above in connection with FIG. 3 to form a single amorphous accommodating layer.

In accordance with an embodiment, the step of depositing the monocrystalline oxide layer 65 is terminated by depositing a second template layer 64, which can be 1-10 monolayers of titanium, barium, barium and oxygen, or titanium and oxygen. A layer 66 of a monocrystalline compound semiconductor material is then deposited overlying second template layer 64 by a process of molecular beam epitaxy. The deposition of layer 66 is initiated by depositing a layer of arsenic onto template 64. This initial step is followed by depositing gallium and arsenic to form monocrystalline gallium arsenide 66. Alternatively, strontium can be substituted for barium in the above example.

In accordance with a further embodiment, a semiconductor component, generally indicated by a dashed line 68 is formed in compound semiconductor layer 66. Semiconductor component 68 can be formed by processing steps conventionally used in the fabrication of gallium arsenide or other III-V compound semiconductor material devices. Semiconductor component 68 can be any active or passive component, and preferably is a semiconductor laser, light emitting diode, photodetector, heterojunction bipolar transistor (HBT), high frequency MESFET, or other component that utilizes and takes advantage of the physical properties of compound semiconductor materials. A metallic conductor schematically indicated by the line 70 can be formed to electrically couple device 68 and device 56, thus implementing an integrated device that includes at least one component formed in silicon substrate 52 and one device formed in monocrystalline compound semiconductor material layer 66. Although illustrative structure 50 has been described as a structure formed on a silicon substrate 52 and having a barium (or strontium) titanate layer 65 and a gallium arsenide layer 66, similar devices can be fabricated using other substrates, monocrystalline oxide layers and other compound semiconductor layers as described elsewhere in this disclosure.

FIG. 25 illustrates a semiconductor structure 71 in accordance with a further embodiment. Structure 71 includes a monocrystalline semiconductor substrate 73 such as a monocrystalline silicon wafer that includes a region 75 and a region 76. An electrical component schematically illustrated by the dashed line 79 is formed in region 75 using conventional silicon device processing techniques commonly used in the semiconductor industry. Using process steps similar to those described above, a monocrystalline oxide layer 80 and an intermediate amorphous silicon oxide layer 83 are formed overlying region 76 of substrate 73. A template layer 84 and subsequently a monocrystalline semiconductor layer 87 are formed overlying monocrystalline oxide layer 80. In accordance with a further embodiment, an additional monocrystalline oxide layer 88 is formed overlying layer 87 by process steps similar to those used to form layer 80, and an additional monocrystalline semiconductor layer 90 is formed overlying monocrystalline oxide layer 88 by process steps similar to those used to form layer 87. In accordance with one embodiment, at least one of layers 87 and 90 are formed from a compound semiconductor material. Layers 80 and 83 may be subject to an annealing process as described above in connection with FIG. 3 to form a single amorphous accommodating layer.

A semiconductor component generally indicated by a dashed line 92 is formed at least partially in monocrystalline semiconductor layer 87. In accordance with one embodiment, semiconductor component 92 may include a field effect transistor having a gate dielectric formed, in part, by monocrystalline oxide layer 88. In addition, monocrystalline semiconductor layer 90 can be used to implement the gate electrode of that field effect transistor. In accordance with one embodiment, monocrystalline semiconductor layer 87 is formed from a group III-V compound and semiconductor component 92 is a radio frequency amplifier that takes advantage of the high mobility characteristic of group III-V component materials. In accordance with yet a further embodiment, an electrical interconnection schematically illustrated by the line 94 electrically interconnects component 79 and component 92. Structure 71 thus integrates components that take advantage of the unique properties of the two monocrystalline semiconductor materials.

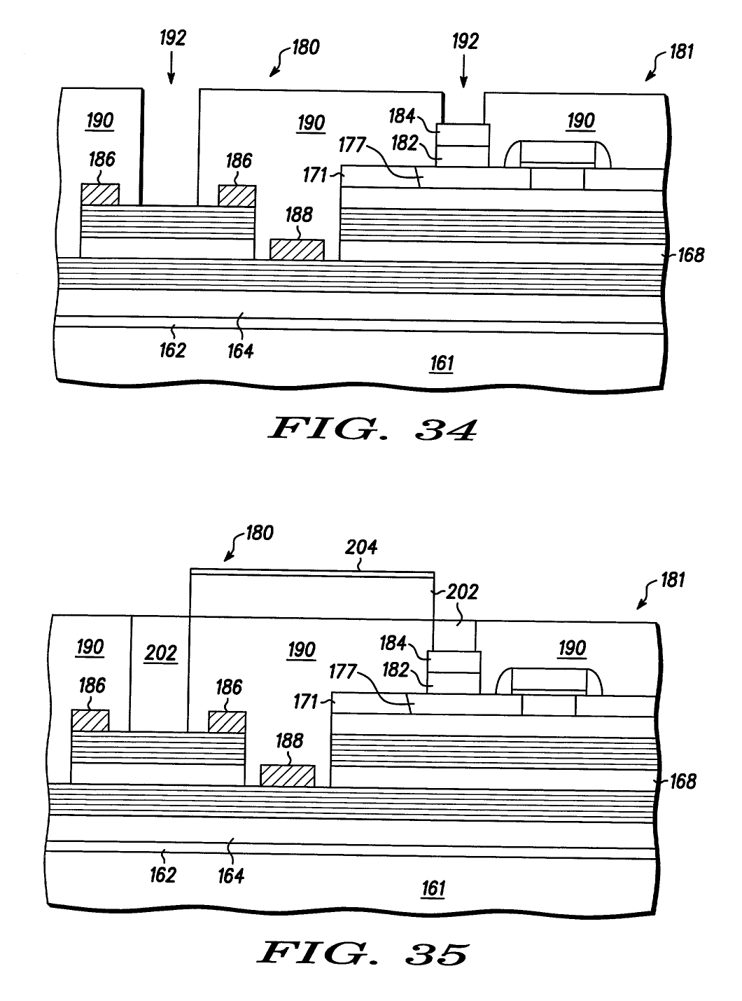

Attention is now directed to a method for forming exemplary portions of illustrative composite semiconductor structures or composite integrated circuits like 50 or 71. In particular, the illustrative composite semiconductor structure or integrated circuit 103 shown in FIGS. 26-30 includes a compound semiconductor portion 1022, a bipolar portion 1024, and a MOS portion 1026. In FIG. 26, a p-type doped, monocrystalline silicon substrate 110 is provided having a compound semiconductor portion 1022, a bipolar portion 1024, and an MOS portion 1026. Within bipolar portion 1024, the monocrystalline silicon substrate 110 is doped to form an N+ buried region 1102. A lightly p-type doped epitaxial monocrystalline silicon layer 1104 is then formed over the buried region 1102 and the substrate 110. A doping step is then performed to create a lightly n-type doped drift region 1117 above the N+ buried region 1102. The doping step converts the dopant type of the lightly p-type epitaxial layer within a section of the bipolar region 1024 to a lightly n-type monocrystalline silicon region. A field isolation region 1106 is then formed between and around the bipolar portion 1024 and the MOS portion 1026. A gate dielectric layer 1110 is formed over a portion of the epitaxial layer 1104 within MOS portion 1026, and the gate electrode 1112 is then formed over the gate dielectric layer 1110. Sidewall spacers 1115 are formed along vertical sides of the gate electrode 1112 and gate dielectric layer 1110.

A p-type dopant is introduced into the drift region 1117 to form an active or intrinsic base region 1114. An n-type, deep collector region 1108 is then formed within the bipolar portion 1024 to allow electrical connection to the buried region 1102. Selective n-type doping is performed to form N+ doped regions 1116 and the emitter region 1120. N+ doped regions 1116 are formed within layer 1104 along adjacent sides of the gate electrode 1112 and are source, drain, or source/drain regions for the MOS transistor. The N+ doped regions 1116 and emitter region 1120 have a doping concentration of at least 1E19 atoms per cubic centimeter to allow ohmic contacts to be formed. A p-type doped region is formed to create the inactive or extrinsic base region 1118 which is a P+ doped region (doping concentration of at least 1E19 atoms per cubic centimeter).

In the embodiment described, several processing steps have been performed but are not illustrated or further described, such as the formation of well regions, threshold adjusting implants, channel punchthrough prevention implants, field punchthrough prevention implants, as well as a variety of masking layers. The formation of the device up to this point in the process is performed using conventional steps. As illustrated, a standard N-channel MOS transistor has been formed within the MOS region 1026, and a vertical NPN bipolar transistor has been formed within the bipolar portion 1024. Although illustrated with a NPN bipolar transistor and a N-channel MOS transistor, device structures and circuits in accordance with various embodiments may additionally or alternatively include other electronic devices formed using the silicon substrate. As of this point, no circuitry has been formed within the compound semiconductor portion 1022.

After the silicon devices are formed in regions 1024 and 1026, a protective layer 1122 is formed overlying devices in regions 1024 and 1026 to protect devices in regions 1024 and 1026 from potential damage resulting from device formation in region 1022. Layer 1122 may be formed of, for example, an insulating material such as silicon oxide or silicon nitride.

All of the layers that have been formed during the processing of the bipolar and MOS portions of the integrated circuit, except for epitaxial layer 1104 but including protective layer 1122, are now removed from the surface of compound semiconductor portion 1022. A bare silicon surface is thus provided for the subsequent processing of this portion, for example in the manner set forth above.

An accommodating buffer layer 124 is then formed over the substrate 110 as illustrated in FIG. 27. The accommodating buffer layer will form as a monocrystalline layer over the properly prepared (i.e., having the appropriate template layer) bare silicon surface in portion 1022. The portion of layer 124 that forms over portions 1024 and 1026, however, may be polycrystalline or amorphous because it is formed over a material that is not monocrystalline, and therefore, does not nucleate monocrystalline growth. The accommodating buffer layer 124 typically is a monocrystalline metal oxide or nitride layer and typically has a thickness in a range of approximately 2-100 nanometers. In one particular embodiment, the accommodating buffer layer is approximately 5-15 nm thick. During the formation of the accommodating buffer layer, an amorphous intermediate layer 122 is formed along the uppermost silicon surfaces of the integrated circuit 103. This amorphous intermediate layer 122 typically includes an oxide of silicon and has a thickness and range of approximately 1-5 nm. In one particular embodiment, the thickness is approximately 2 nm. Following the formation of the accommodating buffer layer 124 and the amorphous intermediate layer 122, a template layer 125 is then formed and has a thickness in a range of approximately one to ten monolayers of a material. In one particular embodiment, the material includes titanium-arsenic, strontium-oxygen-arsenic, or other similar materials as previously described with respect to FIGS. 1-5

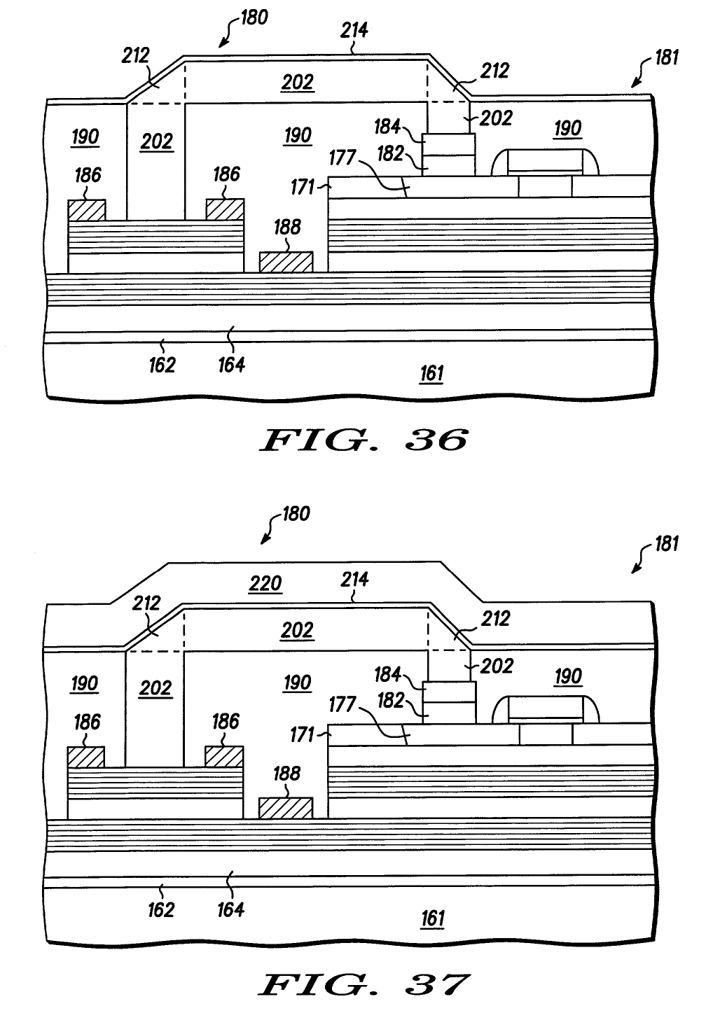

A monocrystalline compound semiconductor layer 132 is then epitaxially grown overlying the monocrystalline portion of accommodating buffer layer 124 as shown in FIG. 28. The portion of layer 132 that is grown over portions of layer 124 that are not monocrystalline may be polycrystalline or amorphous. The compound semiconductor layer can be formed by a number of methods and typically includes a material such as gallium arsenide, aluminum gallium arsenide, indium phosphide, or other compound semiconductor materials as previously mentioned. The thickness of the layer is in a range of approximately 1-5,000 nm, and more preferably 100-2000 nm. Furthermore, additional monocrystalline layers may be formed above layer 132, as discussed in more detail below in connecion with FIGS. 31-32.

In this particular embodiment, each of the elements within the template layer are also present in the accommodating buffer layer 124, the monocrystalline compound semiconductor material 132, or both. Therefore, the delineation between the template layer 125 and its two immediately adjacent layers disappears during processing. Therefore, when a transmission electron microscopy (TEM) photograph is taken, an interface between the accommodating buffer layer 124 and the monocrystalline compound semiconductor layer 132 is seen.

After at least a portion of layer 132 is formed in region 1022, layers 122 and 124 may be subject to an annealing process as described above in connection with FIG. 3 to form a single amorphous accommodating layer. If only a portion of layer 132 is formed prior to the anneal process, the remaining portion may be deposited onto structure 103 prior to further processing.

At this point in time, sections of the compound semiconductor layer 132 and the accommodating buffer layer 124 (or of the amorphous accommodating layer if the annealing process described above has been carried out) are removed from portions overlying the bipolar portion 1024 and the MOS portion 1026 as shown in FIG. 29. After the section of the compound semiconductor layer and the accommodating buffer layer 124 are removed, an insulating layer 142 is formed over protective layer 1122. The insulating layer 142 can include a number of materials such as oxides, nitrides, oxynitrides, low-k dielectrics, or the like. As used herein, low-k is a material having a dielectric constant no higher than approximately 3.5. After the insulating layer 142 has been deposited, it is then polished or etched to remove portions of the insulating layer 142 that overlie monocrystalline compound semiconductor layer 132.

A transistor 144 is then formed within the monocrystalline compound semiconductor portion 1022. A gate electrode 148 is then formed on the monocrystalline compound semiconductor layer 132. Doped regions 146 are then formed within the monocrystalline compound semiconductor layer 132. In this embodiment, the transistor 144 is a metal-semiconductor field-effect transistor (MESFET). If the MESFET is an n-type MESFET, the doped regions 146 and at least a portion of monocrystalline compound semiconductor layer 132 are also n-type doped. If a p-type MESFET were to be formed, then the doped regions 146 and at least a portion of monocrystalline compound semiconductor layer 132 would have just the opposite doping type. The heavier doped (N⁺) regions 146 allow ohmic contacts to be made to the monocrystalline compound semiconductor layer 132. At this point in time, the active devices within the integrated circuit have been formed. Although not illustrated in the drawing figures, additional processing steps such as formation of well regions, threshold adjusting implants, channel punchthrough prevention implants, field punchthrough prevention implants, and the like may be performed in accordance with the present invention. This particular embodiment includes an n-type MESFET, a vertical NPN bipolar transistor, and a planar n-channel MOS transistor. Many other types of transistors, including P-channel MOS transistors, p-type vertical bipolar transistors, p-type MESFETs, and combinations of vertical and planar transistors, can be used. Also, other electrical components, such as resistors, capacitors, diodes, and the like, may be formed in one or more of the portions 1022, 1024, and 1026.

Processing continues to form a substantially completed integrated circuit 103 as illustrated in FIG. 30. An insulating layer 152 is formed over the substrate 110. The insulating layer 152 may include an etch-stop or polish-stop region that is not illustrated in FIG. 30. A second insulating layer 154 is then formed over the first insulating layer 152. Portions of layers 154, 152, 142, 124, and 1122 are removed to define contact openings where the devices are to be interconnected. Interconnect trenches are formed within insulating layer 154 to provide the lateral connections between the contacts. As illustrated in FIG. 30, interconnect 1562 connects a source or drain region of the n-type MESFET within portion 1022 to the deep collector region 1108 of the NPN transistor within the bipolar portion 1024. The emitter region 1120 of the NPN transistor is connected to one of the doped regions 1116 of the n-channel MOS transistor within the MOS portion 1026. The other doped region 1116 is electrically connected to other portions of the integrated circuit that are not shown. Similar electrical connections are also formed to couple regions 1118 and 1112 to other regions of the integrated circuit.

A passivation layer 156 is formed over the interconnects 1562, 1564, and 1566 and insulating layer 154. Other electrical connections are made to the transistors as illustrated as well as to other electrical or electronic components within the integrated circuit 103 but are not illustrated in the FIGS. Further, additional insulating layers and interconnects may be formed as necessary to form the proper interconnections between the various components within the integrated circuit 103.

As can be seen from the previous embodiment, active devices for both compound semiconductor and Group IV semiconductor materials can be integrated into a single integrated circuit. Because there is some difficulty in incorporating both bipolar transistors and MOS transistors within a same integrated circuit, it may be possible to move some of the components within bipolar portion into the compound semiconductor portion 1024 or the MOS portion 1026. Therefore, the requirement of special fabricating steps solely used for making a bipolar transistor can be eliminated. Therefore, there would only be a compound semiconductor portion and a MOS portion to the integrated circuit.

In still another embodiment, an integrated circuit can be formed such that it includes an optical laser in a compound semiconductor portion and an optical interconnect (waveguide) to a MOS transistor within a Group IV semiconductor region of the same integrated circuit. FIGS. 31-37 include illustrations of one embodiment.

FIG. 31 includes an illustration of a cross-section view of a portion of an integrated circuit 160 that includes a monocrystalline silicon wafer 161. An amorphous intermediate layer 162 and an accommodating buffer layer 164, similar to those previously described, have been formed over wafer 161. Layers 162 and 164 may be subject to an annealing process as described above in connection with FIG. 3 to form a single amorphous accommodating layer. In this specific embodiment, the layers needed to form the optical laser will be formed first, followed by the layers needed for the MOS transistor. In FIG. 31, the lower mirror layer 166 includes alternating layers of compound semiconductor materials. For example, the first, third, and fifth films within the optical laser may include a material such as gallium arsenide, and the second, fourth, and sixth films within the lower mirror layer 166 may include aluminum gallium arsenide or vice versa. Layer 168 includes the active region that will be used for photon generation. Upper mirror layer 170 is formed in a similar manner to the lower mirror layer 166 and includes alternating films of compound semiconductor materials. In one particular embodiment, the upper mirror layer 170 may be p-type doped compound semiconductor materials, and the lower mirror layer 166 may be n-type doped compound semiconductor materials.

Another accommodating buffer layer 172, similar to the accommodating buffer layer 164, is formed over the upper mirror layer 170. In an alternative embodiment, the accommodating buffer layers 164 and 172 may include different materials. However, their function is essentially the same in that each is used for making a transition between a compound semiconductor layer and a monocrystalline Group IV semiconductor layer. Layer 172 may be subject to an annealing process as described above in connection with FIG. 3 to form an amorphous accommodating layer. A monocrystalline Group IV semiconductor layer 174 is formed over the accommodating buffer layer 172. In one particular embodiment, the monocrystalline Group IV semiconductor layer 174 includes germanium, silicon germanium, silicon germanium carbide, or the like.

In FIG. 32, the MOS portion is processed to form electrical components within this upper monocrystalline Group IV semiconductor layer 174. As illustrated in FIG. 32, a field isolation region 171 is formed from a portion of layer 174. A gate dielectric layer 173 is formed over the layer 174, and a gate electrode 175 is formed over the gate dielectric layer 173. Doped regions 177 are source, drain, or source/drain regions for the transistor 181, as shown. Sidewall spacers 179 are formed adjacent to the vertical sides of the gate electrode 175. Other components can be made within at least a part of layer 174. These other components include other transistors (n-channel or p-channel), capacitors, transistors, diodes, and the like.

A monocrystalline Group IV semiconductor layer is epitaxially grown over one of the doped regions 177. An upper portion 184 is P+ doped, and a lower portion 182 remains substantially intrinsic (undoped) as illustrated in FIG. 32. The layer can be formed using a selective epitaxial process. In one embodiment, an insulating layer (not shown) is formed over the transistor 181 and the field isolation region 171. The insulating layer is patterned to define an opening that exposes one of the doped regions 177. At least initially, the selective epitaxial layer is formed without dopants. The entire selective epitaxial layer may be intrinsic, or a p-type dopant can be added near the end of the formation of the selective epitaxial layer. If the selective epitaxial layer is intrinsic, as formed, a doping step may be formed by implantation or by furnace doping. Regardless how the P+ upper portion 184 is formed, the insulating layer is then removed to form the resulting structure shown in FIG. 32.

The next set of steps is performed to define the optical laser 180 as illustrated in FIG. 33. The field isolation region 171 and the accommodating buffer layer 172 are removed over the compound semiconductor portion of the integrated circuit. Additional steps are performed to define the upper mirror layer 170 and active layer 168 of the optical laser 180. The sides of the upper mirror layer 170 and active layer 168 are substantially coterminous.

Contacts 186 and 188 are formed for making electrical contact to the upper mirror layer 170 and the lower mirror layer 166, respectively, as shown in FIG. 33. Contact 186 has an annular shape to allow light (photons) to pass out of the upper mirror layer 170 into a subsequently formed optical waveguide.

An insulating layer 190 is then formed and patterned to define optical openings extending to the contact layer 186 and one of the doped regions 177 as shown in FIG. 34. The insulating material can be any number of different materials, including an oxide, nitride, oxynitride, low-k dielectric, or any combination thereof. After defining the openings 192, a higher refractive index material 202 is then formed within the openings to fill them and to deposit the layer over the insulating layer 190 as illustrated in FIG. 35. With respect to the higher refractive index material 202, “higher” is in relation to the material of the insulating layer 190 (i.e., material 202 has a higher refractive index compared to the insulating layer 190). Optionally, a relatively thin lower refractive index film (not shown) could be formed before forming the higher refractive index material 202. A hard mask layer 204 is then formed over the high refractive index layer 202. Portions of the hard mask layer 204, and high refractive index layer 202 are removed from portions overlying the opening and to areas closer to the sides of FIG. 35.

The balance of the formation of the optical waveguide, which is an optical interconnect, is completed as illustrated in FIG. 36. A deposition procedure (possibly a dep-etch process) is performed to effectively create sidewalls sections 212. In this embodiment, the sidewall sections 212 are made of the same material as material 202. The hard mask layer 204 is then removed, and a low refractive index layer 214 (low relative to material 202 and layer 212) is formed over the higher refractive index material 212 and 202 and exposed portions of the insulating layer 190. The dash lines in FIG. 36 illustrate the border between the high refractive index materials 202 and 212. This designation is used to identify that both are made of the same material but are formed at different times.

Processing is continued to form a substantially completed integrated circuit as illustrated in FIG. 37. A passivation layer 220 is then formed over the optical laser 180 and MOSFET transistor 181. Although not shown, other electrical or optical connections are made to the components within the integrated circuit but are not illustrated in FIG. 37. These interconnects can include other optical waveguides or may include metallic interconnects.

In other embodiments, other types of lasers can be formed. For example, another type of laser can emit light (photons) horizontally instead of vertically. If light is emitted horizontally, the MOSFET transistor could be formed within the substrate 161, and the optical waveguide would be reconfigured, so that the laser is properly coupled (optically connected) to the transistor. In one specific embodiment, the optical waveguide can include at least a portion of the accommodating buffer layer. Other configurations are possible.

Clearly, these embodiments of integrated circuits having compound semiconductor portions and Group IV semiconductor portions, are meant to illustrate what can be done and are not intended to be exhaustive of all possibilities or to limit what can be done. There is a multiplicity of other possible combinations and embodiments. For example, the compound semiconductor portion may include light emitting diodes, photodetectors, diodes, or the like, and the Group IV semiconductor can include digital logic, memory arrays, and most structures that can be formed in conventional MOS integrated circuits. By using what is shown and described herein, it is now simpler to integrate devices that work better in compound semiconductor materials with other components that work better in Group IV semiconductor materials. This allows a device to be shrunk, the manufacturing costs to decrease, and yield and reliability to increase.

Although not illustrated, a monocrystalline Group IV wafer can be used in forming only compound semiconductor electrical components over the wafer. In this manner, the wafer is essentially a “handle” wafer used during the fabrication of the compound semiconductor electrical components within a monocrystalline compound semiconductor layer overlying the wafer. Therefore, electrical components can be formed within III-V or II-VI semiconductor materials over a wafer of at least approximately 200 millimeters in diameter and possibly at least approximately 300 millimeters.

By the use of this type of substrate, a relatively inexpensive “handle” wafer overcomes the fragile nature of the compound semiconductor wafers by placing them over a relatively more durable and easy to fabricate base material. Therefore, an integrated circuit can be formed such that all electrical components, and particularly all active electronic devices, can be formed within the compound semiconductor material even though the substrate itself may include a Group IV semiconductor material. Fabrication costs for compound semiconductor devices should decrease because larger substrates can be processed more economically and more readily, compared to the relatively smaller and more fragile, conventional compound semiconductor wafers.

A composite integrated circuit may include components that provide electrical isolation when electrical signals are applied to the composite integrated circuit. The composite integrated circuit may include a pair of optical components, such as an optical source component and an optical detector component. An optical source component may be a light generating semiconductor device, such as an optical laser (e.g., the optical laser illustrated in FIG. 33), a photo emitter, a diode, etc. An optical detector component may be a light-sensitive semiconductor junction device, such as a photodetector, a photodiode, a bipolar junction, a transistor, etc.

A composite integrated circuit may include processing circuitry that is formed at least partly in the Group IV semiconductor portion of the composite integrated circuit. The processing circuitry is configured to communicate with circuitry external to the composite integrated circuit. The processing circuitry may be electronic circuitry, such as a microprocessor, RAM, logic device, decoder, etc.

For the processing circuitry to communicate with external electronic circuitry, the composite integrated circuit may be provided with electrical signal connections to the external electronic circuitry. The composite integrated circuit may also have internal optical communications connections for connecting the processing circuitry in the composite integrated circuit to the electrical connections with the external circuitry. Optical components in the composite integrated circuit may provide the optical communications connections which may electrically isolate the electrical signals in the communications connections from the processing circuitry. Together, the electrical and optical communications connections may be for communicating information, such as data, control, timing, etc.

A pair of optical components (an optical source component and an optical detector component) in the composite integrated circuit may be configured to pass information. Information that is received or transmitted between the optical pair may be from or for the electrical communications connection between the processing circuitry and the external circuitry while providing electrical isolation for the processing circuitry. If desired, a plurality of optical component pairs may be included in the composite integrated circuit for providing a plurality of communications connections and for providing isolation. For example, a composite integrated circuit receiving a plurality of data bits may include a pair of optical components for communication of each data bit.

In operation, for example, an optical source component in a pair of components may be configured to generate light (e.g., photons) based on receiving electrical signals from an electrical signal connection with the external circuitry. An optical detector component in the pair of components may be optically connected to the source component to generate electrical signals based on detecting light generated by the optical source component. Information that is communicated between the source and detector components may be digital or analog.

If desired the reverse of this configuration may be used. An optical source component that is responsive to the on-board processing circuitry may be coupled to an optical detector component to have the optical source component generate an electrical signal for use in communications with external circuitry. A plurality of such optical component pair structures may be used for providing two-way connections. In some applications where synchronization is desired, a first pair of optical components may be coupled to provide data communications and a second pair may be coupled for communications synchronization information.

For clarity and brevity, optical detector components that are discussed below are discussed primarily in the context of optical detector components that have been formed in a compound semiconductor portion of a composite integrated circuit. In application, the optical detector component may be formed in many suitable ways (e.g., formed from silicon, etc.).

A composite integrated circuit will typically have an electric connection for a power supply and a ground connection. The power and ground connections are in addition to the communications connections that are discussed above. Processing circuitry in a composite integrated circuit may include electrically isolated communications connections and include electrical connections for power and ground. In most known applications, power supply and ground connections are usually well-protected by circuitry to prevent harmful external signals from reaching the composite integrated circuit. A communications ground may be isolated from the ground signal in communications connections that use a ground communications signal.

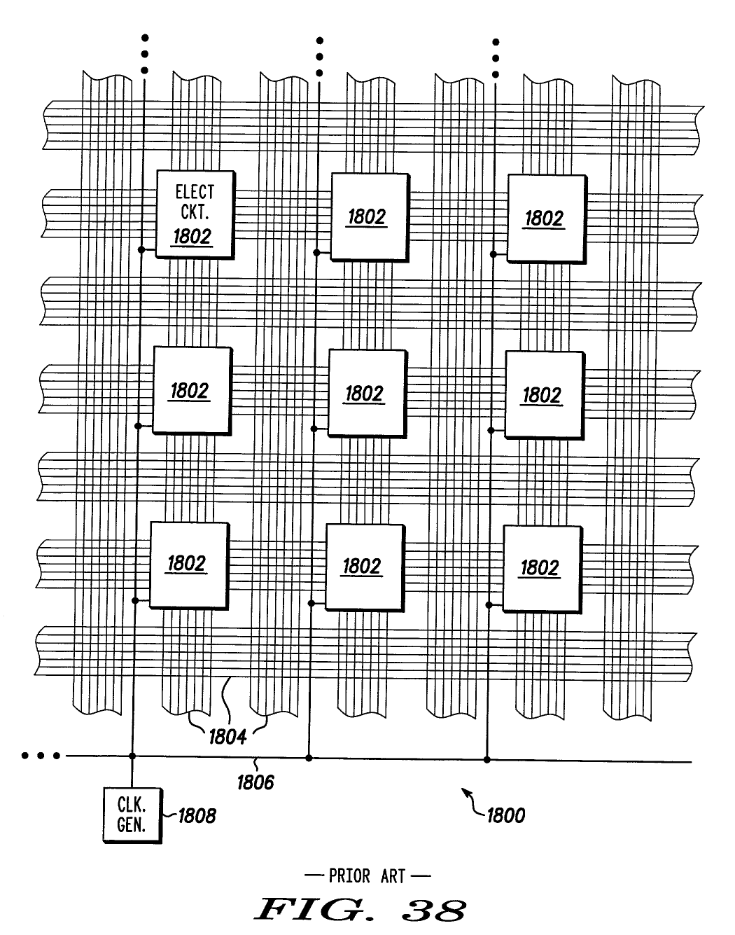

In a further embodiment, optical data buses may be used to implement data/control, global clock wiring, and any other suitable interconnect component of an integrated circuit. FIG. 38 represents a portion of a conventional semiconductor integrated circuit 1800, which can be a portion of a chip or an integrated wafer. Integrated circuit 1800 includes a plurality of electrical circuits 1802, data/control busses 1804, global clock wiring 1806, and optional clock generator 1808 (clock signals alternatively can be received by integrated circuit 1800 from a clock generator coupled to, but not located on, integrated circuit 1800). Fabrication of integrated circuit 1800 is typically based on a Group IV semiconductor, such as silicon or germanium. Signals on integrated circuit 1800 are generated, propagated, and processed electrically (i.e., based on signal voltage and current characteristics).

Each electrical circuit 1802 represents a circuit area of any type, size, or complexity for performing one or more data processing, memory, or logic functions of any type or complexity. For example, one or more electrical circuits 1802 can be memory arrays or digital logic (e.g., arithmetic logic units or address generation units). One or more electrical circuits 1802 can be subprocessors or system controllers of a multi-processor integrated circuit. Still other electrical circuits 1802 can be simple multiplexers, latches, or inverters. Electrical circuits 1802 can include various interconnections of transistors, diodes, capacitors, resistors, and other known electrical or electronic elements, components, or devices. Transistors can be, for example, NPN or PNP bipolar transistors or NMOS or PMOS FETs. Electrical circuits 1802 can be fabricated in any known semiconductor technology (e.g., a bipolar or CMOS technology), or combinations of known technologies (e.g., bipolar and FET technologies). Each electrical circuit 1802 has at least one input and at least one output.

Data/control busses 1804 and global clock wiring 1806 are typically metal wires fabricated on one or more wiring planes. Global clock wiring 1806 propagates clock signals to electrical circuits 1802, while busses 1804 propagate data and control signals from any electrical circuit 1802 to any other electrical circuit 1802. Intersecting busses 1804 are selectively interconnected to enable data and control signals to be propagated to and from each electrical circuit 1802. Similarly, global clock signals may be routed through various wiring planes in order to reach each electrical circuit 1802. As shown, busses 1804 and global clock wiring 1806 typically consume large areas of integrated circuit 1800.

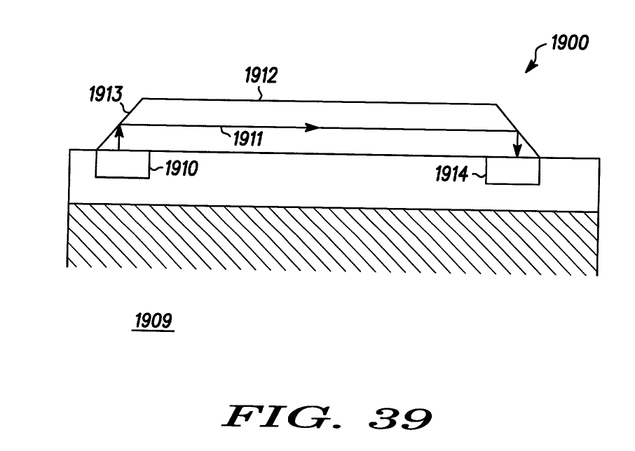

Advantageously, many long data busses and most, if not all, long global clock lines can be replaced with an optical bus 1900, an exemplary embodiment of which is shown in FIG. 39, in accordance with the present invention. (For clarity, FIG. 39 does not show the individual component layers illustrated in previous FIGs.) Optical bus 1900 is disposed on a substantially monocrystalline semiconductor substrate 1909, such as silicon, upon which multiple epitaxial layers are deposited to permit formation of active optical devices, including solid state lasers and photodetectors, in the manner described above. Optical bus 1900 preferably includes laser 1910 and includes waveguide 1912 and photodetector 1914.

Laser 1910 generates an optical signal 1911 preferably in response to an electrical signal received from, for example, an output of an electrical circuit 1802. Laser 1910 may be a vertical cavity surface emitting laser (“VCSEL”), which has an active area that emits laser light along an axis substantially perpendicular to the substrate surface. VCSELs can be fabricated to emit light upward, as shown in FIG. 39, or downward. If a VCSEL is fabricated to emit light downward, waveguide 1912 is fabricated before and below laser 1910. Alternatively, laser 1910 can be an edge-coupled laser. An edge-coupled laser is disposed on the surface of the substrate and has an active area that emits laser light in a plane parallel to the substrate surface.

Waveguide 1912 is a structure through which optical signals (i.e., light waves) propagate from a first location to a second location. Waveguide 1912 is made of a material that has an index of refraction different from the index of refraction of adjacent insulating material. Preferably, the waveguide material has an index of refraction greater than the index of refraction of the insulating material. This facilitates operation of the waveguide in a single optical mode. Furthermore, the waveguide preferably has cross-sectional dimensions that also facilitate operation of the waveguide in a single optical mode. As discussed above, the insulating material can be an oxide, a nitride, an oxynitride, a low-k dielectric, or any combination thereof. As also discussed above, the waveguide material can be, for example, strontium titanate, barium titanate, strontium barium titanate, or a combination thereof. As shown, for example, in FIGS. 31-37, waveguide 1912 is preferably constructed with materials having a sufficiently high index of refraction to cause substantially total internal reflection of the optical signals passing there through.

Waveguide 1912 is optically coupled to laser 1910 via an optical interconnect portion 1913 disposed above laser 1910. Optical interconnect portion 1913 includes a side wall surface that reflects laser light about 90° so that the laser is properly coupled to an end of the waveguide. The side wall can be formed according to any convenient process, such as photo-assisted etching, dep-etch processing, or preferential chemical etching.

Optical signals advantageously propagate more rapidly through a waveguide than do electrical signals through conventional electrical conductors and vias (which connect conductors on different planes). This is primarily because of the greater impedance of such conductors and vias.

Photodetector 1914 is optically coupled to waveguide 1912, and is a photosensitive element that detects and converts optical signals to electrical signals. Photodetector 1914 is preferably very sensitive, capable of detecting small optical signals, and can be, for example, a photodiode or phototransistor. Alternatively, photodetector 1914 can be any other suitable photosensitive element.

An illustrative method of fabricating optical bus 1900 on a semiconductor substrate is as follows. The substrate has a surface that at least includes a monocrystalline region above which a laser can be formed and a waveguide region (i.e., a monocrystalline, polycrystalline, or amorphous region) above which a waveguide can be formed. The method includes (1) forming an accommodating layer on the substrate; (2) forming a laser above the accommodating layer over the monocrystalline region, using at least one compound semiconductor material; (3) growing a low index bottom cladding; (4) growing a high refractive index layer over the waveguide region; (5) etching a waveguide pattern in the high refractive index layer to form a waveguide core having a longitudinal optical path; and (6) cladding the waveguide core with a suitable cladding material. The cladding material may have a lower index of refraction than the high refractive index layer to support total internal reflection. In the case of a VCSEL that emits light downward, the steps of forming an accommodating layer, etching, and cladding occur before the laser is formed.

As also described in detail further above, optical bus 1900 can be fabricated on an integrated circuit (such as integrated circuit 1800) preferably on top of conventional electrical circuitry. Alternatively or additionally, conventional electrical circuitry can be fabricated on top of optical bus 1900. Optical bus 1900 can therefore advantageously replace or supplement conventional data/control busses and global clock wiring. Thus, an integrated circuit either can be made smaller or can include additional circuitry in the areas made available by the replaced busses and clock wiring. Moreover, optical bus 1900 can propagate clock and control signals and large amounts data over long distances more rapidly with less power or heat dissipation than can conventional electrical conductors.

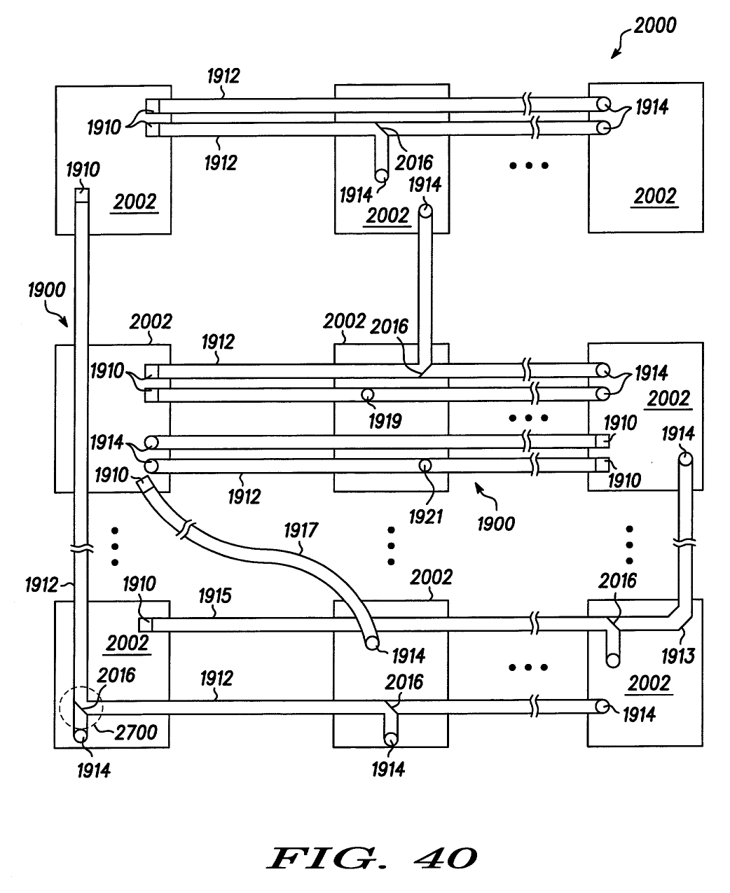

FIG. 40 shows a representative portion of an exemplary embodiment of integrated circuit 2000 using optical busses 1900 to replace conventional data/control busses and global clock lines in accordance with the present invention (for clarity, those busses and control lines not replaced by optical busses 1900 are not shown). Integrated circuit 2000 is preferably fabricated with both compound semiconductor portions and Group IV semiconductor portions (note that the invention is not limited to Group IV semiconductor portions), as described in more detail above. Integrated circuit 2000 is preferably a single chip or integrated wafer, and includes a plurality of Group IV-based electrical circuits 2002 (which are the same as or similar to electrical circuits 1802), a plurality of lasers 1910 (shown as small squares), a plurality of waveguides 1912, a plurality of beam splitters 2016, and a plurality of photodetectors 1914 (shown as small circles). Lasers 1910 are electrically coupled to one or more outputs of electrical circuits 2002 and are optically coupled to a waveguide 1912. Each laser 1910 is preferably controlled electronically by an electrical circuit 2002. Photodetectors 1914 are optically coupled to waveguides 1912 and are electrically coupled to one or more inputs of electrical circuits 2002.

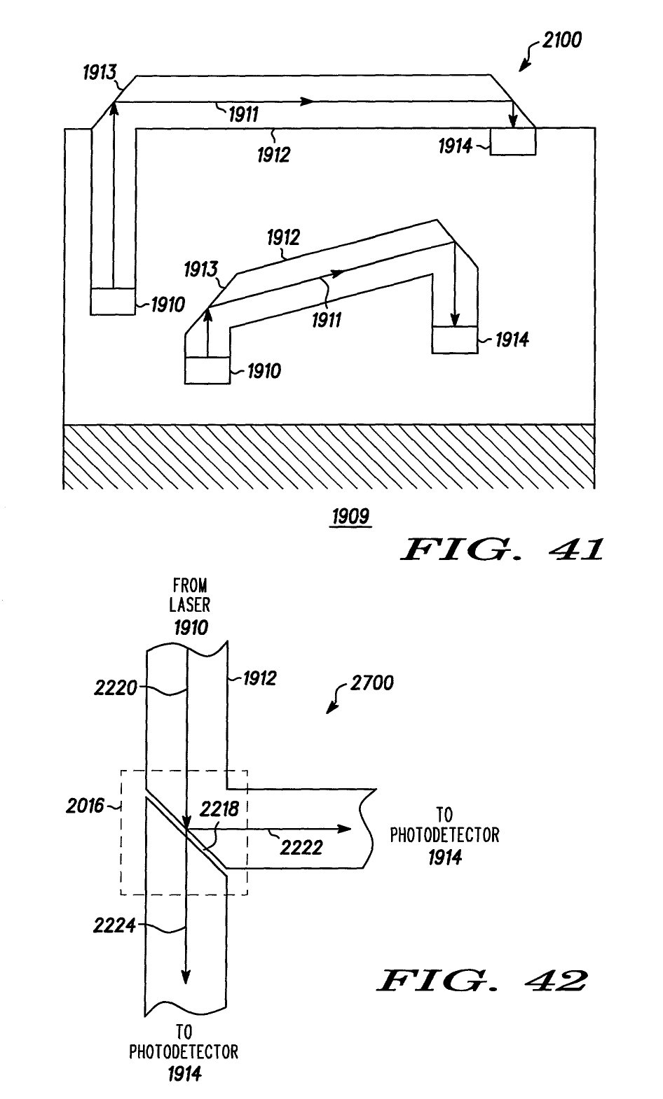

Waveguides 1912 can be in any convenient configuration, and can include one or more straight segments, curved segments (see, e.g., waveguide 1912a), or combinations of both. Waveguides 1912 also can be configured to make right angle turns (see, e.g., waveguide 1912b). Metal or another highly reflective material can be coated on the corner chamfer to increase reflectivity, thus creating an optical path that turns at right angles and is substantially lossless. Waveguides 1912 further can be stacked on top of each other to create additional optical signal propagation planes. An insulating material can be deposited between waveguide planes. Still further, a waveguide 1912 can lie in multiple planes. Thus optical signals can be generated in one plane and detected in another. Some of these optical bus 1900 features are illustrated cross-sectionally in the optical bus embodiments of FIG. 41. (For clarity, FIG. 41 does not show the individual component layers illustrated in previous FIGs.)

Beam splitters 2016 split an optical signal into two optical signals. Alternative embodiments of beam splitters 2016 can split an optical signal into more than two optical signals. Beam splitters 2016 are placed in the optical path of waveguide 1912 regardless of the waveguide's particular geometry, and can be formed, for example, from an air gap between two parallel plates or by a partly metallized mirror. Beam splitters 2016 are optically coupled between lasers 1910 and photodetectors 1914.

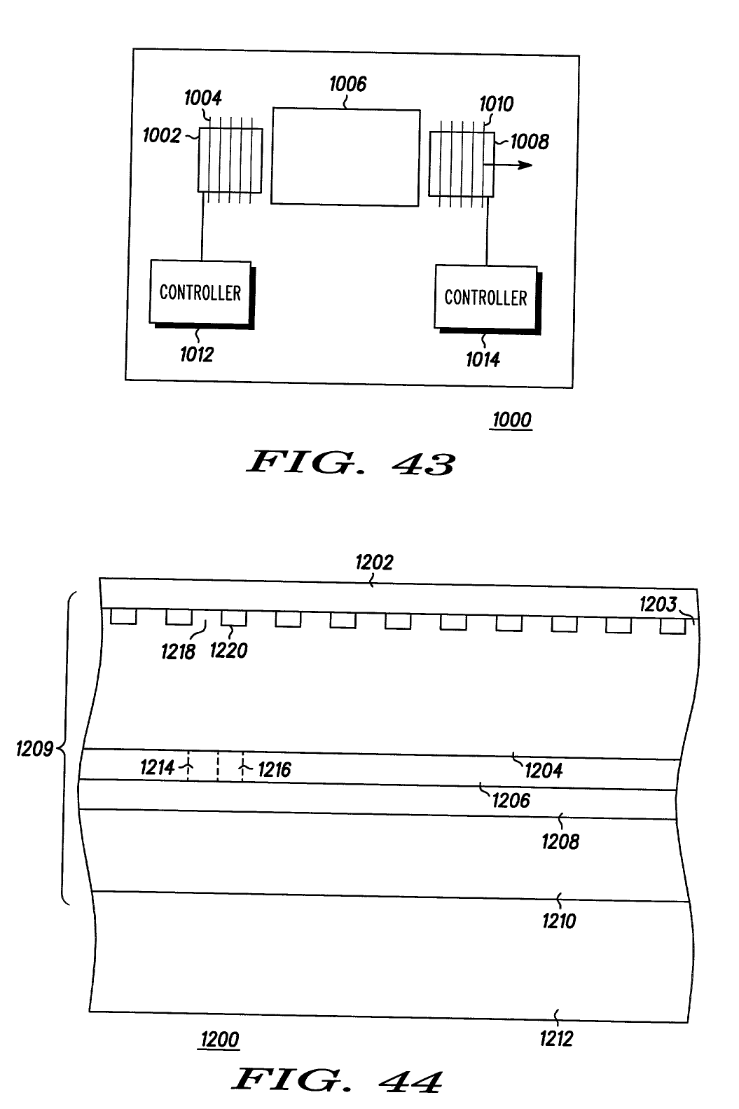

As shown more clearly in FIG. 42, beam splitter 2016 can be integral with waveguide 1912 and includes beam splitter element 2218. Element 2218 can include a thin sheet of a material that has an index of refraction different from the rest of the material of beam splitter 2106. Element 2218 is positioned in the optical path of laser beam 2220 at an angle sufficient to divert first portion 2222 of beam 2220 toward a first photodetector 1914 and second portion 2224 of beam 2220 toward a second photodetector 1914. Alternatively, beam splitter 2016 can be a separate structure optically coupled to two or more waveguides 1912.

To propagate data, clock, or control signals, an appropriate electrical signal is received by laser 1910, which preferably responds by generating an optical signal (in other words, lasers 1910 are preferably electrically modulated). The optical signal then propagates through a waveguide 1912 to one or more destinations. If a signal needs to be propagated to multiple destinations, beam splitters 2016 split the optical signal into two or more optical signals. At a signal destination, a photodetector 1914 detects and converts the optical signal to an electrical signal. Before being propagated to a receiving electrical circuit 2002, electrical signals converted by photodetectors 1914 preferably are first buffered to electrical values required by that receiving circuit 2002. If a signal destination is located under a continuing waveguide 1912, a photodetector 1914 can be coupled at that location (see, e.g., photodetectors 1914a and 1914b in FIG. 40) without significantly adversely affecting an optical signal propagating by that location, because only a fraction of the light signal will be propagating at the correct angle to couple into that photodetector 1914.

Optical busses 1900 also can be used in those integrated circuit 2000 embodiments in which a single clock generator and multiple clock drivers are replaced with simple retriggerable free running clocks located in each electrical circuit 2002. Such free running clocks merely require a periodic synchronizing signal that can be provided by a single laser 1910 coupled optically to multiple beam splitters 2016, waveguides 1912, and photodetectors 1914.

In other embodiments of the present invention, laser 1910 is not included in optical bus 1900. Instead, optical signals are generated on a separate structure by a laser or other suitable device that is appropriately coupled to a waveguide 1912. For example, some integrated circuits may receive optical data or clock signals from other integrated circuits that are part of the same interconnected system or machine. In those cases, optical bus 1900 is constructed without laser 1910 to receive and propagate such externally-generated optical signals to photodetectors 1914.

In sum, optical busses 1900 advantageously provide high-speed signal propagation that can replace significant portions of conventional metal wiring, thus freeing integrated circuit area. Optical busses 1900 that propagate clock signals advantageously eliminate the need for multiple clock drivers, thus reducing power dissipation and freeing additional integrated circuit area. Furthermore, because photodetectors 1914 are highly sensitive, optical signal losses caused by beam splitting or signal propagation through long waveguides do not adversely affect circuit performance or cause clock skewing problems.

In a further embodiment, composite integrated circuits may be fabricated that provide mode-locked optical resonators, such as lasers. Although the mode-locking of the present invention is described primarily in terms of lasers, it will be understood that this is merely an illustrative embodiment and that the principles described hereinafter may be applied to any other suitable optical resonator.

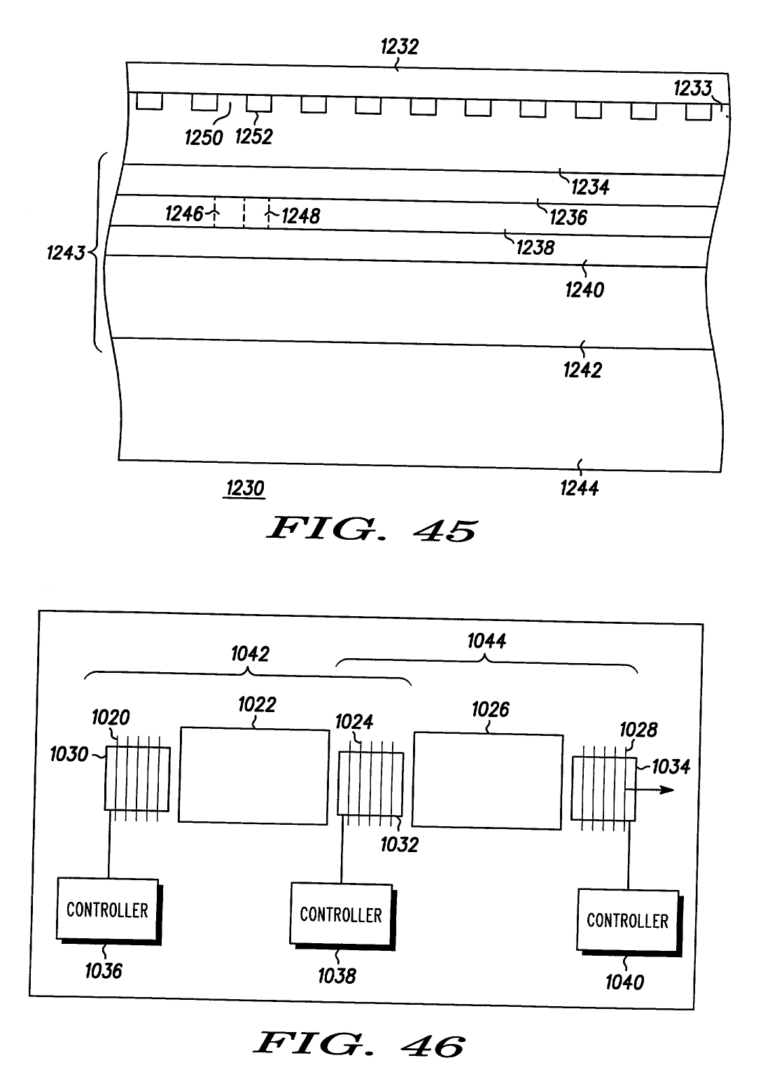

FIG. 43 is a schematic of portion 1000 of a composite integrated circuit in accordance with the present invention having a mode-locked laser. A laser is implemented using periodic gratings 1004 and 1010 and gain medium 1006. Gratings 1004 and 1010 are used as mirrors to allow light to reflect back and forth through gain medium 1006. Gain medium 1006 amplifies the light as the light is bounced between the resonator created by gratings 1004 and 1010. The gratings may be used to tune or modulate the frequency of the laser in the cavity. Because the gratings are implemented in an electro-optic material, electrodes may be deposited above the gratings so that when a voltage is applied, the grating period is changed resulting in the tunability of the resultant laser output. In this manner, the mode phases of the laser are synchronized to a substantially equivalent value, thus mode-locking the laser.

Gratings 1004 and 1010 may be Bragg gratings. For example, gratings 1004 and 1010 may be implemented in BaTiO3 (BTO), which is an electro-optic material. Gratings 1004 and 1010 may be tuned by applying an electric field over them. For example, as shown in FIG. 43, electrodes 1002 and 1008 may be placed over gratings 1004 and 1010, respectively. Controllers 1012 and 1014 are coupled to electrodes 1002 and 1008, respectively, and control the field effected on gratings 1004 and 1010 through electrodes 1002 and 1008, respectively.

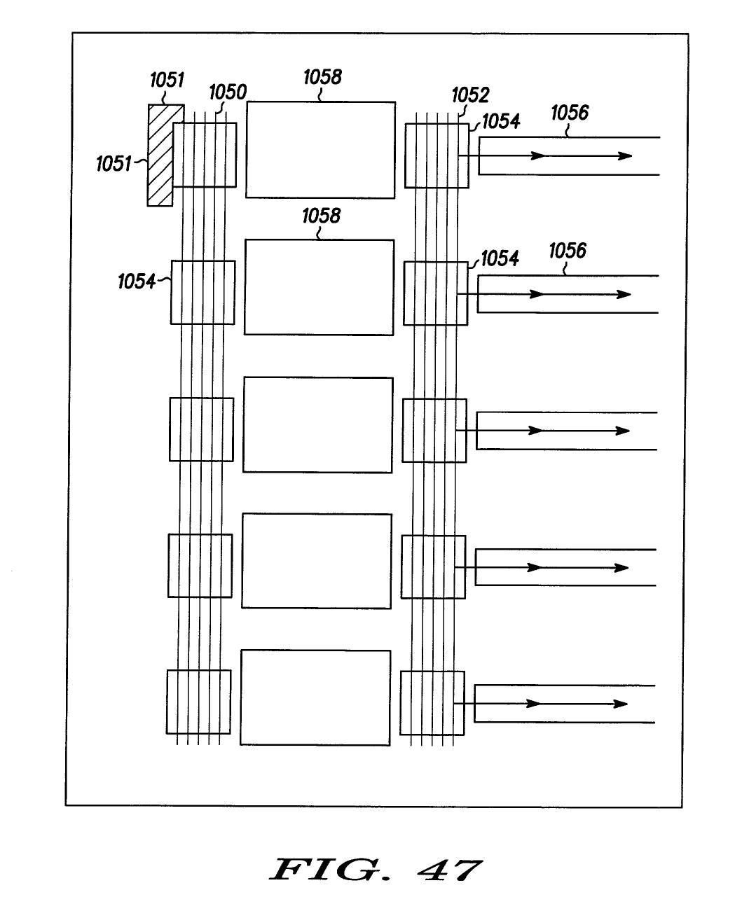

FIG. 44 is a cross-section of the gratings of one embodiment of the present invention. Composite integrated circuit portion 1200 includes non-compound semiconductor substrate 1212, which may be any suitable Group IV substrate, such as silicon. Accommodating layer 1210 is grown over substrate 1212 in accordance with the present invention. Layers 1208, 1206, and 1204 make up optical waveguide 1209. Layer 1208 is a bottom cladding layer, layer 1206 is a waveguide core, and layer 1204 is a top cladding layer. Waveguide 1209 may be fabricated using any suitable material. For example, waveguide 1209 may be fabricated using BTO (and doped BTO), InP (and doped InP), PZT, LiNbO₃, PLZT, glass, plastic, or any other suitable material. Waveguide 1209 may be a single-mode waveguide. Alternatively, waveguide 1209 may be a multi-mode waveguide.

Layer 1204 is etched to produce periodic gratings 1203 (i.e., having substantially equivalent lengths between each grating) on the top of layer 1204. Electrode 1202 is placed over layer 1204.

Portions of waveguide core layer 1206 experience different effective indices of refraction. For example, grating portion 1218 of gratings 1203 produces a particular effective index of refraction in corresponding waveguide core portion 1214, whereas grating portion 1220 of gratings 1203 produces another effective index of refraction in corresponding waveguide portion 1216. These two effective indices of refraction vary periodically in waveguide core layer 1206 corresponding to the period of gratings 1203. When an electric field is applied to gratings 1203 using electrode 1202 and a controller (not shown), the indices of refraction are changed, thus creating a new grating period. This, in effect, allows the resultant optical signal to be tuned.

In another suitable approach, gratings 1004 and 1010 of FIG. 43 may be implemented in a material other than BTO. For example, InGaAsP may be used to implement gratings 1004 and 1010. Any such compound semiconductor that is capable of carrying particular wavelengths of light and is capable of producing Bragg-style gratings may be used in accordance with the present invention.

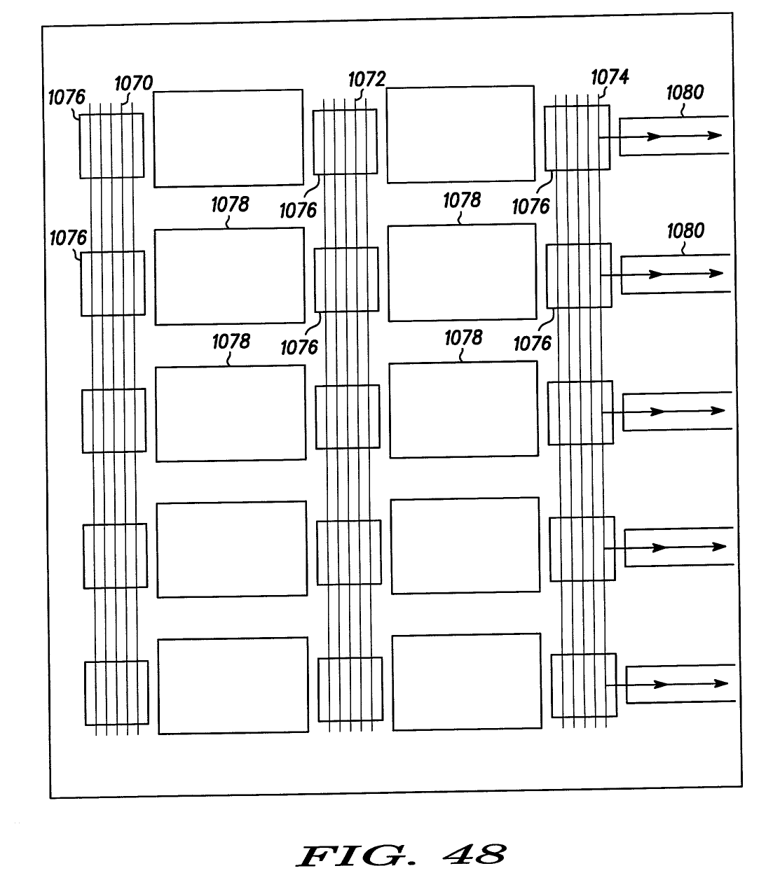

For example, FIG. 45 is a cross-section of the gratings of another embodiment of the present invention. Composite integrated circuit portion 1230 includes non-compound semiconductor substrate 1244, which may be any suitable Group IV substrate, such as silicon. Accommodating layer 1242 is grown over substrate 1244 in accordance with the present invention. Layers 1240, 1238, and 1236 make up optical waveguide 1243. Layer 1240 is a bottom cladding layer, layer 1238 is a waveguide core, and layer 1236 is a top cladding layer. Waveguide 1243 may be fabricated using any suitable material. For example, waveguide 1243 may be fabricated using BTO (and doped BTO), InP (and doped InP), PZT, LiNbO₃, PLZT, glass, plastic, or any other suitable material. Waveguide 1243 may be a single-mode waveguide. Alternatively, waveguide 1243 may be a multi-mode waveguide.

Layer 1234 is grown over waveguide 1243. Layer 1234 is etched to produce periodic gratings 1233 (i.e., having substantially equivalent lengths between each grating) on the top of layer 1234. Electrode 1232 is placed over layer 1234. Layer 1234 may be any suitable material, such as InGaAsP.

Portions of waveguide core layer 1238 experience different effective indices of refraction. For example, grating portion 1250 of gratings 1233 produces a particular effective index of refraction in corresponding waveguide core portion 1246, whereas grating portion 1252 of gratings 1233 produces another effective index of refraction in corresponding waveguide portion 1248. These two effective indices of refraction vary periodically in waveguide core layer 1238 corresponding to the period of gratings 1233. When an electric field is applied to gratings 1233 using electrode 1232 and a controller (not shown), the indices of refraction are changed, thus creating a new grating period. This, in effect, allows the resultant optical signal to be tuned.

Referring back to FIG. 43, gain medium 1006 may be any suitable material. In one suitable approach, the material chosen for gain medium 1006 may be based on the wavelength of interest. For example, InP may be used for 1.5 μm wavelengths, AlGaAs may be used for 0.8 μm wavelengths, or AlGaAsP may be used for 1.3 μm. Any such suitable material may be used for gain medium 1006.

As illustrated in FIG. 43, the laser implemented by gratings 1002 and 1008 and by gain medium 1006, may be fabricated along a single optical waveguide or by multiple optical waveguides. That is, a single optical waveguide may be used whereby the ends of the top cladding layer of the waveguide (or a material deposited in the top cladding layer) are etched to produce gratings 1002 and 1008 and the middle portion of the waveguide's core is used as the gain medium. Alternatively, three separate optical waveguides may be optically coupled to one another, whereby two of the optical waveguides are used to implement gratings 1002 and 1008, and the third optical waveguide is used to implement gain medium 1006.

It will be appreciated that the description of materials for the components of the laser of the present invention described above may apply to the entire waveguide in the case where a single waveguide is used. More specifically, a material for the waveguide is chosen that will accommodate a gain medium for amplifying a laser and an electro-optic for tuning the laser. In one suitable arrangement, different layers of the waveguide may be implemented using different materials depending on how the respective layers will be used (e.g., as a gain medium).

Controllers 1012 and 1014 may be one controller. In another suitable approach, controllers 1012 and 1014 may be distinct controllers that are either mutually, or exclusively dependent on one another. In yet another suitable approach, controllers 1012 and 1014 may be separate, independent controllers. Controllers 1012 and 1014 may be any suitable implementation of a controller. For example, controllers 1012 and 1014 may be circuitry (e.g., digital signal processing (DSP) circuitry) integrated into the same circuit as the mode-locked laser in accordance with the present invention. In another suitable approach, controllers 1012 and 1014 may be external controllers that are human-operated (e.g., dials, buttons, levers, etc.). Any such suitable controller may be used.

The wavelength of the laser will be λ_{B}=2nₑΛ/k where nₑ is the effective refractive index, k is an integer for the order of the grating (e.g., k=1 for a first-order grating) and Λ is the grating period. By applying an electric field over at least one of the gratings in the electro-optic material, the index of refraction, nₑ, is changed.

Moreover, nₑ is also a function of temperature. Thus, the laser mode will shift with temperature. Also, if there is more than one mode under the laser gain curve and the index of refraction of the grating shifts enough, an adjacent laser mode may become excited and emitted. This is equivalent to mode hopping.

In addition, because of the piezoelectric properties of the buffer layer, the grating period, Λ, may be changed by applying an electric field over this layer.

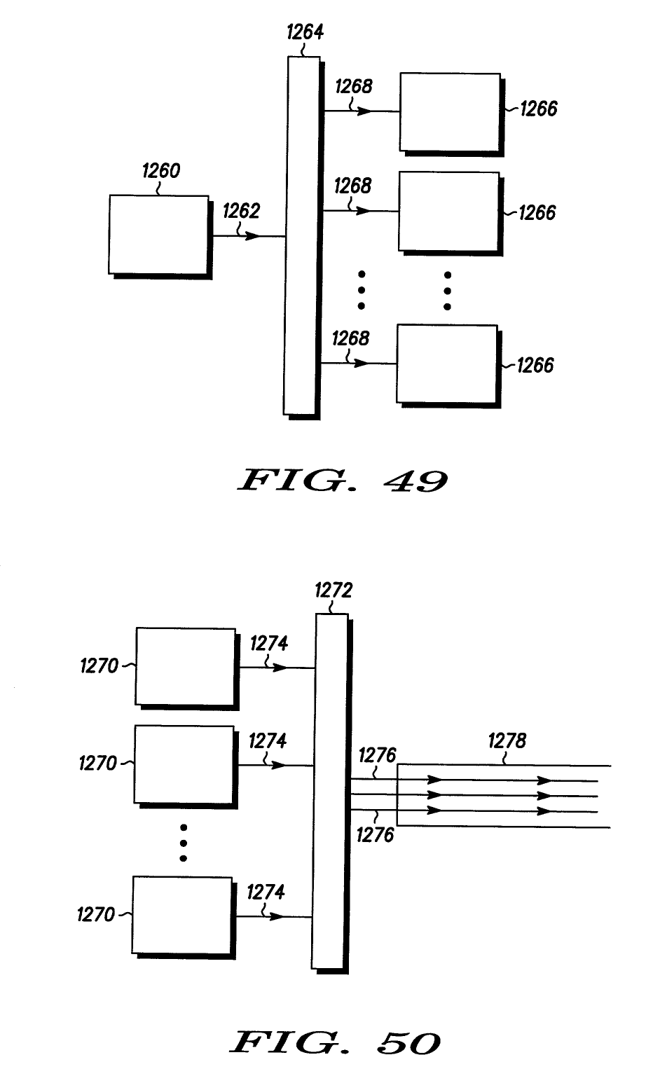

In one suitable arrangement, injection-locking may be used with a mode-locked laser. Injection-locking allows particular properties of one laser to be transferred to another laser. FIG. 46 is a schematic of a portion of a composite integrated circuit in accordance with the present invention that shows injection-locking with mode-locking. Gratings 1020 and 1024 act as mirrors for laser 1042. Grating 1024 and 1028 act as mirrors for laser 1044. Electrodes 1030, 1032, and 1034 are placed over gratings 1020, 1024, and 1028, respectively. Controllers 1036, 1038, and 1040 are coupled to electrodes 1030, 1032, and 1034, respectively. Each controller controls its respective electrode to tune the gratings.

When laser 1042 is mode-locked, laser 1044 will be mode-locked as well. Injection-locking thus provides for the transferability of optical properties from one master laser to another slave laser. Injection-locking may be used for any suitable purpose. For example, injection-locking may be used for wavelength conversion.

Injection-locked lasers may be implemented using a single optical waveguide. More particularly, three sets of gratings and two gain medium portions that may make up an injection-locked arrangement may be fabricated using a single continuous optical waveguide. Alternatively, multiple optical waveguides may be optically coupled to one another.

In one suitable arrangement, multiple mode-locked lasers may be fabricated in parallel (e.g., using an array structure). For example, continuous gratings on both ends of an array of gain media may be fabricated (e.g., by having the optical waveguides used to implement the continuous gratings share a top cladding layer). Separate electrodes may be placed over each section for the separate lasers in the array. An optical waveguide may be aligned with the output of each of the lasers to guide the laser beam to a destination on or off the chip.

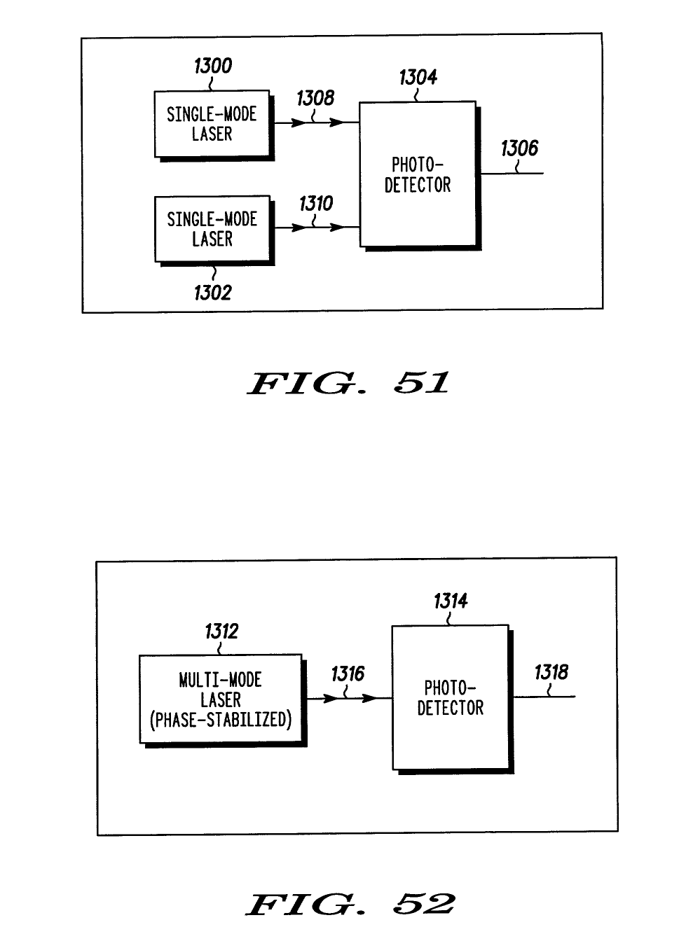

This arrangement is illustrated in FIG. 47, which shows a portion of an integrated circuit that has an array of gain media 1058 with continuous gratings 1050 and 1052 implemented as the mirrors of the laser. Each laser in the array may have separate electrodes 1054 placed over gratings 1050 and 1052. This allows each laser to be independently tuned by controllers (not shown). Waveguides 1056 may be aligned with the mode-locked lasers to carry the output optical signal to any suitable destination.

In one suitable approach, gratings 1051 and 1052 may be electrically isolated from one another and from other components using isolation trenches. For example, isolation trenches 1051 may surround each grating of an array of lasers. Only one isolated grating is shown in FIG. 47 to avoid over-complicating the illustration. It will be understood that any or all gratings, or any other suitable components, may be electrically isolated using isolation trenches.

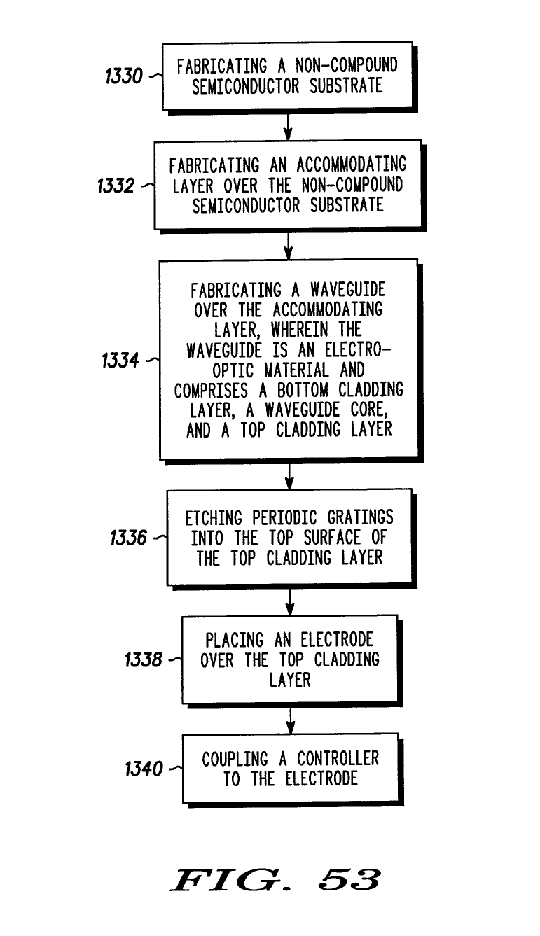

An injection-locked, mode-locked laser array may be fabricated having three continuous gratings with two arrays of gain media in between the continuous gratings as illustrated in FIG. 48. Continuous gratings 1070 and 1072 are used as mirrors for the mode-locked laser that is coupled to the laser that uses continuous grating 1072 and 1074 for its mirrors. Gain medium arrays (i.e., made up of gain media 1078) are arranged in between continuous gratings 1070 and 1072 and in between continuous gratings 1072 and 1074 to implement the two lasers. Separate electrodes 1076 are placed over gratings 1070, 1072, and 1074. This allows each laser to be independently tuned by controllers (not shown). Waveguides 1080 may be aligned with the mode-locked lasers to carry the output optical signal to any suitable destination.

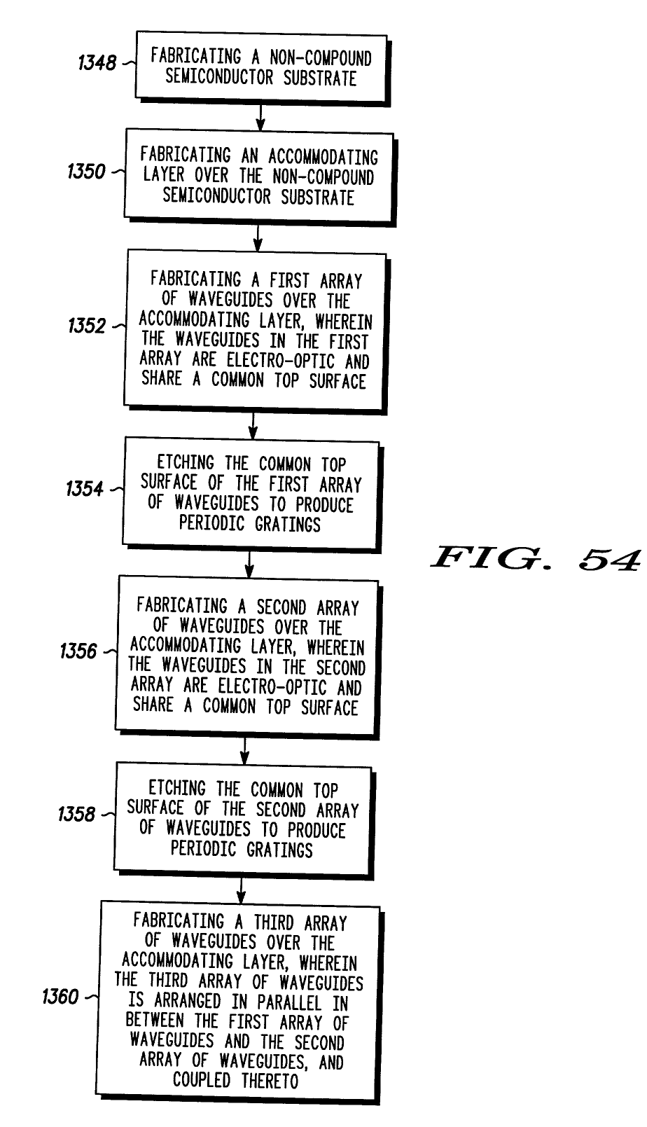

In one suitable arrangement, only one stabilized mode-locked laser may be used to inject-lock an array of slave lasers. This may be accomplished by splitting the optical signal from the master laser and injecting them into slave lasers. This is illustrated in FIG. 49, which shows stabilized, mode-locked master laser 1260 that produces laser beam 1262. Beam splitter 1264 may be used to produce multiple beams 1268 that are fed into slave lasers 1266. Thus, slave lasers 1266 are injection-locked using the optical properties of master laser 1260. This arrangement may be used for, for example, wavelength stabilization of multiple optical transmitters.

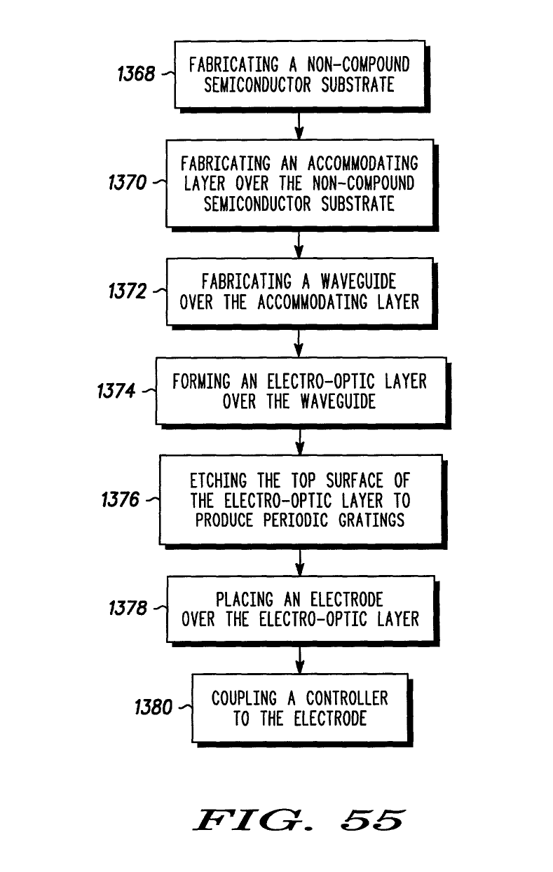

The parallel laser arrangement of FIGS. 47 and 48 may allow for different wavelength lasers beams to be created and transmitted using different waveguides. In another suitable arrangement, a single waveguide may be used to carry different laser beams that may have originated from different sources. For example, FIG. 50 shows lasers 1270 that are mode-locked in accordance with the present invention (e.g., laser arrays of FIG. 47 or 48). Laser beams 1274 produced by corresponding laser 1270 are combined by lens 1272 into optical output 1276, which is inputted into a single waveguide 1278. Lens 1272 may be any suitable optical component implemented in the composite integrated circuit of the present invention, such as a diffractive optical element. Waveguide 1278 may be any suitable waveguide that is capable of carrying multiple wavelengths.

In another suitable arrangement, waveguides, such as waveguides 1056 and 1080 of FIGS. 47 and 48, respectively, may be branches that converge into a single waveguide. That is, the optical signals carries by waveguides 1056 and 1080, respectively, may be combined into a single waveguide by fabricating the waveguides to combine into a single waveguide.

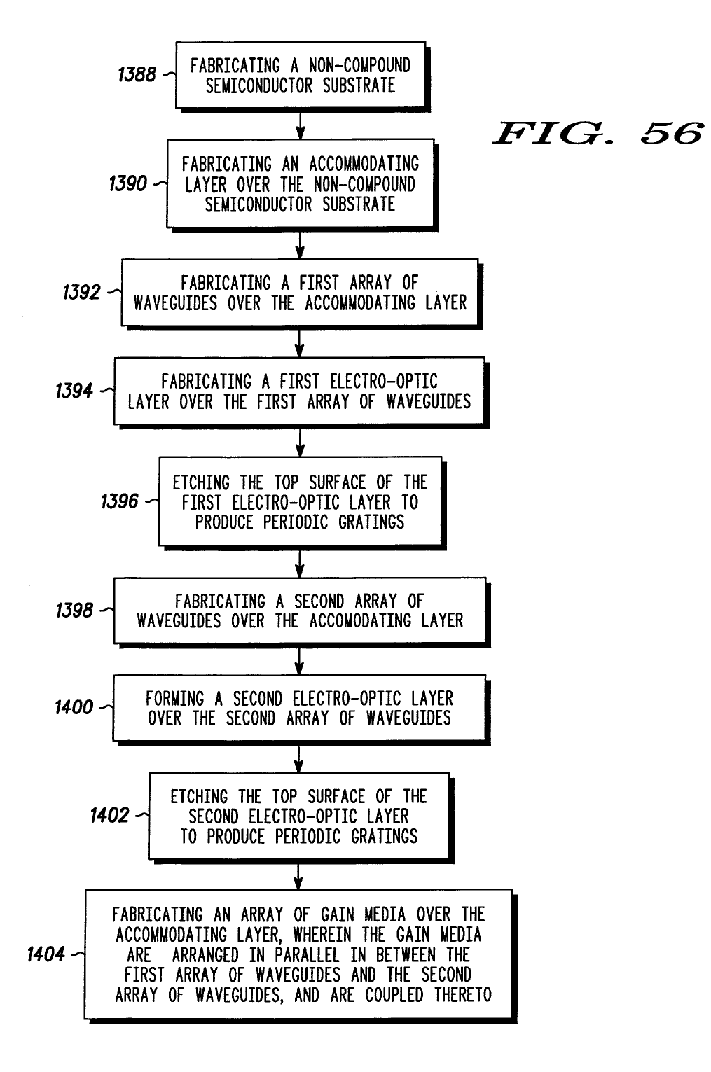

In one suitable embodiment of the mode-locked laser of the present invention, optical signals may be converted into RF or millimeter waves. An arrangement for performing this conversion is illustrated in FIG. 51. FIG. 51 illustrates the case where the output of a single-mode laser is converted into an electrical signal, which may then be converted into an RF or millimeter wave. This may be accomplished by using at least two single-mode lasers 1300 and 1302 to direct their respective laser beams 1308 and 1310 into a non-linear device (e.g., photodetector 1304) simultaneously. Signal 1306 may be used to derive the difference in frequencies of lasers 1300 and 1302.

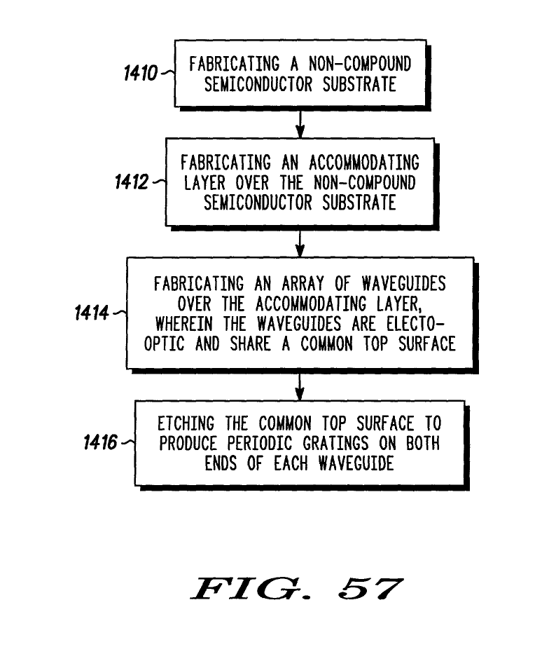

Another suitable arrangement for obtaining RF or millimeter waves from an optical signal is illustrated in FIG. 52. In this case, the output of a multi-mode laser (i.e., a laser having more than one mode) is converted into an RF or millimeter wave. Multi-mode laser 1312 is phase-stabilized using an approach such as one of those illustrated in FIGS. 43 and 46. Thus, multi-mode laser 1312 is mode-locked. Laser beam 1316 is then directed into a non-linear device such as photodetector 1314 which produces signal 1318, which in turn may be used to produce an RF or millimeter wave signal.

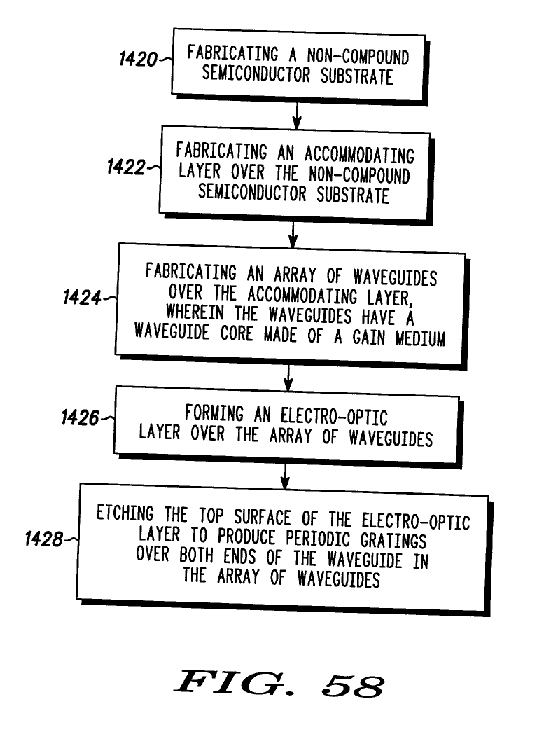

FIGS. 53-58 are flow charts of illustrative steps involved in fabricating the tunable lasers of the present invention. FIG. 53 is a flow chart of illustrative steps involved in fabricating a tunable laser by etching gratings into the waveguide to act as mirrors. The steps include: fabricating a non-compound semiconductor substrate (1330); fabricating an accommodating layer over the non-compound semiconductor substrate (1332); fabricating a waveguide over the accommodating layer, wherein the waveguide is an electro-optic material and comprises a bottom cladding layer, a waveguide core, and a top cladding layer (1334); etching periodic gratings into the top surface of the top cladding layer (1336); placing an electrode over the top cladding layer (1338); and coupling a controller to the electrode (1340).

FIG. 54 is a flow chart of illustrative steps involved in fabricating a tunable laser array having lasers implemented along multiple waveguides with gratings etched into the waveguides to act as mirrors. The steps include: fabricating a non-compound semiconductor substrate (1348); fabricating an accommodating layer over the non-compound semiconductor substrate (1350); fabricating a first array of waveguides over the accommodating layer, wherein the waveguides in the first array are electro-optic and share a common top surface (1352); etching the common top surface of the first array of waveguides to produce periodic gratings (1354); fabricating a second array of waveguides over the accommodating layer, wherein the waveguides in the second array are electro-optic and share a common top surface (1356); etching the common top surface of the second array of waveguides to produce periodic gratings (1358); and fabricating a third array of waveguides over the accommodating layer, wherein the third array of waveguides is arranged in parallel in between the first array of waveguides and the second array of waveguides, and coupled thereto (1360).

FIG. 55 is a flow chart of illustrative steps involved in fabricating a tunable laser by etching gratings into an electro-optic material formed over a waveguide. The steps include: fabricating a non-compound semiconductor substrate (1368); fabricating an accommodating layer over the non-compound semiconductor substrate (1370); fabricating a waveguide over the accommodating layer (1372); forming an electro-optic layer over the waveguide (1374); etching the top surface of the electro-optic layer to produce periodic gratings (1376); placing an electrode over the electro-optic layer (1378); and coupling a controller to the electrode (1380).

FIG. 56 is a flow chart of illustrative steps involved in fabricating a tunable laser array having lasers implemented along multiple waveguides. An electro-optic material is formed over the waveguides and is etched with gratings that act as mirrors. The steps include: fabricating a non-compound semiconductor substrate (1388); fabricating an accommodating layer over the non-compound semiconductor substrate (1390);fabricating a first array of waveguides over the accommodating layer (1392); forming a first electro-optic layer over the first array of waveguides (1394);etching the top surface of the first electro-optic layer to produce periodic gratings (1396); fabricating a second array of waveguides over the accommodating layer (1398); forming a second electro-optic layer over the second array of waveguides (1400); etching the top surface of the second electro-optic layer to produce periodic gratings (1402); and fabricating an array of gain media over the accommodating layer, wherein the gain media are arranged in parallel in between the first array of waveguides and the second array of waveguides, and are coupled thereto (1404).

FIG. 57 is a flow chart of illustrative steps involved in fabricating a tunable laser array having lasers, each with a waveguide that is etched to produce gratings to be used as mirrors. The steps include: fabricating a non-compound semiconductor substrate (1410); fabricating an accommodating layer over the non-compound semiconductor substrate (1412); fabricating an array of waveguides over the accommodating layer, wherein the waveguides are electro-optic and share a common top surface (1414); and etching the common top surface to produce periodic gratings on both ends of each waveguide (1416).

FIG. 58 is a flow chart of illustrative steps involved in fabricating a tunable laser array having lasers, each with a waveguide over which is formed an electro-optic material in which gratings are etched to act as mirrors. The steps include: fabricating a non-compound semiconductor substrate (1420); fabricating an accommodating layer over the non-compound semiconductor substrate (1422); fabricating an array of waveguides over the accommodating layer, wherein the waveguides have a waveguide core made of a gain medium (1424); forming an electro-optic layer over the array of waveguides (1426); and etching the top surface of the electro-optic layer to produce periodic gratings over both ends of the waveguides in the array of waveguides (1428).

The flow charts of FIGS. 53-58 are merely illustrative. It will be appreciated that any suitable modifications to the steps recited therein may be made.

Thus, a tunable laser array in composite integrated circuitry is provided. One skilled in the art will appreciate that the present invention can be practiced by other than the described embodiments, which are presented for purposes of illustration and not of limitation, and the present invention is limited only by the claims which follow.

As used herein, the terms “comprises,” “comprising,” or any other variation thereof, are intended to cover a non-exclusive inclusion, such that a process, method, article, or apparatus that comprises a list of elements includes not only those elements but may also include other elements not expressly listed or inherent to such process, method, article, or apparatus.

What is claimed is:

1. A composite integrated circuit comprising:
a non-compound semiconductor substrate;
an accommodating layer fabricated over the non-compound semiconductor substrate;
a waveguide fabricated over the accommodating layer, wherein the waveguide is an electro-optic material and comprises a bottom cladding layer, a waveguide core, and a top cladding layer, and wherein the top cladding layer is etched to produce periodic gratings at the top surface of the top cladding layer;
an electrode placed over the top cladding layer; and
a controller that is coupled to the electrode.

2. The composite integrated circuit of claim 1 wherein the top cladding is etched at both ends to produce periodic gratings at the top surface of the top cladding layer, and wherein the waveguide core is a gain medium.

3. The composite integrated circuit of claim 2 wherein the electrode is placed over the gratings at one of the ends of the top cladding and further comprising a second electrode that is placed over the gratings at the other end of the top cladding.

4. The composite integrated circuit of claim 3 further comprising a second controller that is coupled to the second electrode.

5. The composite integrated circuit of claim 3 wherein the second electrode is coupled to the controller.

6. The composite integrated circuit of claim 1 wherein the top cladding is etched at both ends and at a portion between both ends to produce periodic gratings.

7. The composite integrated circuit of claim 1 further comprising:
a second waveguide fabricated over the accommodating layer, wherein the second waveguide comprises a second bottom cladding layer, a second waveguide core, and a second top cladding layer, and wherein the second top cladding layer is etched to produce periodic gratings at the top surface of the second top cladding layer;
a second electrode placed over the second top cladding layer; and
a gain medium placed in between and coupled to the waveguide and to the second waveguide.

8. The composite integrated circuit of claim 7 further comprising a second controller that is coupled to the second electrode.

9. The composite integrated circuit of claim 7 wherein the second electrode is coupled to the controller.

10. The composite integrated circuit of claim 7 further comprising:
a third waveguide fabricated over the accommodating layer, wherein the third waveguide comprises a third bottom cladding layer, a third waveguide core, and a third top cladding layer, and wherein the third top cladding layer is etched to produce periodic gratings at the top surface of the third top cladding layer;
a third electrode placed over the third top cladding layer; and
a second gain medium placed in between and coupled to the third waveguide and to the second waveguide.

11. The composite integrated circuit of claim 10 further comprising a third controller that is coupled to the third electrode.

12. The composite integrated circuit of claim 10 wherein the third electrode is coupled to the controller.

13. The composite integrated circuit of claim 1 wherein the waveguide is selected from a group consisting of InP, BaTiO₃, PZT, LiNbO₃, PLZT, plastic, glass, and a combination thereof.

14. The composite integrated circuit of claim 1 further comprising a photodetector that accepts as an input two optical signals, each optical signal originating from a single-mode laser, wherein the photodetector produces a millimeter wave output.

15. The composite integrated circuit of claim 1 further comprising a photodetector that accepts as an input an optical signal from a multi-mode laser, wherein the photodetector produces a millimeter wave output.

16. The composite integrated circuit of claim 1 wherein the waveguide is a single-mode waveguide.

17. The composite integrated circuit of claim 1 wherein the waveguide is a multi-mode waveguide.

18. A composite integrated circuit comprising:
a non-compound semiconductor substrate;
an accommodating layer fabricated over the non-compound semiconductor substrate;
a first array of waveguides fabricated over the accommodating layer, wherein the waveguides in the first array are electro-optic and share a common top surface, and wherein the common top surface is etched to produce periodic gratings;
a second array of waveguides fabricated over the accommodating layer, wherein the waveguides in the second array are electro-optic and share a common top surface, and wherein the common top surface is etched to produce periodic gratings; and
a third array of waveguides fabricated over the accommodating layer, wherein the third array of waveguides is arranged in parallel in between the first array of waveguides and the second array of waveguides, and coupled thereto.

19. The composite integrated circuit of claim 18 further comprising individual electrodes placed over each waveguide in the first array of waveguides and in the second array of waveguides.

20. The composite integrated circuit of claim 18 further comprising isolation trenches etched adjacent to the periodic gratings of the first array of waveguides and the second array of waveguides.

21. The composite integrated circuit of claim 18 further comprising a fourth array of waveguides that accepts the optical outputs of the second array of waveguides.

22. The composite integrated circuit of claim 18 further comprising:
a fourth array of waveguides fabricated over the accommodating layer, wherein the waveguides in the fourth array share a common top surface, and wherein the common top surface is etched to produce periodic gratings; and
a fifth array of waveguides fabricated over the accommodating layer, wherein the waveguides in the fifth array waveguides are arranged in parallel in between the second array of waveguides and the fourth array of waveguides and coupled thereto.

23. The composite integrated circuit of claim 22 further comprising electrodes that are individual placed over each waveguide in the fourth array of waveguides.

24. The composite integrated circuit of claim 18 further comprising:
a lens that accepts optical outputs of the second array of waveguides; and
an output waveguide that accepts the lens's optical output.

25. The composite integrated circuit of claim 18 further comprising a fourth array of waveguides that are optically coupled to the second array of waveguides, wherein the fourth array of waveguide converge into a single waveguide.

26. The composite integrated circuit of claim 18 wherein the waveguides of the first array and the second array are single-mode waveguides.

27. The composite integrated circuit of claim 18 wherein the waveguides of the first array and the second array are multi-mode waveguides.

28. The composite integrated circuit of claim 18 further comprising:
a mode-locked laser; and
a beam splitter that accepts an optical input from the mode-locked laser and outputs a plurality of optical signals that are optically coupled to the first array of waveguides.

29. A composite integrated circuit comprising:
a non-compound semiconductor substrate;
an accommodating layer fabricated over the non-compound semiconductor substrate;
a waveguide fabricated over the accommodating layer;
an electro-optic layer formed over the waveguide, wherein the electro-optic layer is etched to produce periodic gratings;
an electrode placed over the electro-optic layer above the waveguide; and
a controller that is coupled to the electrode.

30. The composite integrated circuit of claim 29 wherein the electro-optic layer is etched at both ends to produce periodic gratings, and wherein the waveguide comprises a waveguide core that is a gain medium.

31. The composite integrated circuit of claim 30 wherein the electrode is placed over the gratings at one of the ends of the electro-optic layer and further comprising a second electrode that is placed over the gratings at the other end of the electro-optic layer.

32. The composite integrated circuit of claim 31 further comprising a second controller that is coupled to the second electrode.

33. The composite integrated circuit of claim 31 wherein the second electrode is coupled to the controller.

34. The composite integrated circuit of claim 29 wherein the electro-optic layer is etched at both ends and at a portion between both ends to produce periodic gratings, and wherein the waveguide comprises a waveguide core that is a gain medium.

35. The composite integrated circuit of claim 29 further comprising:
a second waveguide fabricated over the accommodating layer;
a second electro-optic layer formed over the second waveguide, wherein the second electro-optic layer is etched to form periodic gratings;
a second electrode placed over the second electro-optic layer above the second waveguide; and
a gain medium placed in between the waveguide and the second waveguide, and coupled thereto.

36. The composite integrated circuit of claim 35 further comprising a second controller that is coupled to the second electrode.

37. The composite integrated circuit of claim 35 wherein the second electrode is coupled to the controller.

38. The composite integrated circuit of claim 35 further comprising:
a third waveguide fabricated over the accommodating layer;
a third electro-optic layer formed over the third waveguide, wherein the third electro-optic layer is etched to produce periodic gratings;
a third electrode placed over the third electro-optic layer above the third waveguide; and
a second gain medium placed in between the third waveguide and the second waveguide, and coupled thereto.

39. The composite integrated circuit of claim 38 further comprising a third controller that is coupled to the third electrode.

40. The composite integrated circuit of claim 38 wherein the third electrode is coupled to the controller.

41. The composite integrated circuit of claim 29 wherein the waveguide is selected from a group consisting of InP, BaTiO₃, PZT, LiNbO₃, PLZT, plastic, glass, and any combination thereof.

42. The composite integrated circuit of claim 29 wherein the electro-optic layer is selected from a group consisting of BaTiO₃, and InGaAsP.

43. The composite integrated circuit of claim 29 further comprising a photodetector that accepts as an input two optical signals, each optical signal originating from a single-mode laser, wherein the photodetector produces a millimeter wave output.

44. The composite integrated circuit of claim 29 further comprising a photodetector that accepts as an input an optical signal from a multi-mode laser, wherein the photodetector produces a millimeter wave output.

45. The composite integrated circuit of claim 29 wherein the waveguide is a single-mode waveguide.

46. The composite integrated circuit of claim 29 wherein the waveguide is a multi-mode waveguide.

47. A composite integrated circuit comprising:
a non-compound semiconductor substrate;
an accommodating layer fabricated over the non-compound semiconductor substrate;
a first array of waveguides fabricated over the accommodating layer;
a first electro-optic layer formed over the first array of waveguides, wherein the first electro-optic layer is etched to produce periodic gratings;
a second array of waveguides fabricated over the accommodating layer;
a second electro-optic layer formed over the second array of waveguides, wherein the second electro-optic layer is etched to produce periodic gratings; and
an array of gain media fabricated over the accommodating layer, wherein the gain media are arranged in parallel in between the first array of waveguides and the second array of waveguides, and are coupled thereto.

48. The composite integrated circuit of claim 47 further comprising individual electrodes placed over each waveguide in the first array of waveguides and in the second array of waveguides.

49. The composite integrated circuit of claim 47 further comprising isolation trenches etched adjacent to the periodic gratings of the first electro-optic layer and the second electro-optic layer.

50. The composite integrated circuit of claim 47 further comprising a third array of waveguides that accepts the optical outputs of the second array of waveguides.

51. The composite integrated circuit of claim 47 further comprising:
a third array of waveguides fabricated over the accommodating layer; and
a third electro-optic layer formed over the third array of waveguides, wherein the third electro-optic layer is etched to produce periodic gratings; and
a second array of gain media fabricated over the accommodating layer, wherein the gain media in the second array of gain media are arranged in parallel in between the second array of waveguides and the third array of waveguides, and are coupled thereto.

52. The composite integrated circuit of claim 47 further comprising:
a lens that accepts optical outputs of the second array of waveguides; and
an output waveguide that accepts the lens's optical output.

53. The composite integrated circuit of claim 47 further comprising a third array of waveguides that are optically coupled to the second array of waveguides, wherein the third array of waveguides converge into a single waveguide.

54. The composite integrated circuit of claim 47 wherein the first electro-optic layer is selected from a group consisting of InP and BaTiO₃.

55. The composite integrated circuit of claim 47 wherein the second electro-optic layer is selected from a group consisting of InP and BaTiO₃.

56. The composite integrated circuit of claim 47 wherein the waveguides of the first array and of the second array are single-mode waveguides.

57. The composite integrated circuit of claim 47 wherein the waveguides of the first array and of the second array are multi-mode waveguides.

58. The composite integrated circuit of claim 47 further comprising:
a mode-locked laser; and
a beam splitter that accepts an optical input from the mode-locked laser and outputs a plurality of optical signals that are optically coupled to the first array of waveguides.

59. A composite integrated circuit comprising:
a non-compound semiconductor substrate;
an accommodating layer fabricated over the non-compound semiconductor substrate; and
an array of waveguides fabricated over the accommodating layer, wherein the waveguides are electro-optic and share a common top surface, and wherein the common top surface is etched to produce periodic gratings on both ends of each waveguide, and wherein the waveguide core of each of the waveguide is a gain medium.

60. The composite integrated circuit of claim 59 further comprising an electrode placed over each of the gratings.

61. The composite integrated circuit of claim 59 further comprising isolation trenches etched adjacent to the periodic gratings of the array of waveguides.

62. The composite integrated circuit of claim 59 further comprising a second array of waveguides that accept the optical outputs of the array of waveguides.

63. The composite integrated circuit of claim 59 further comprising a second array of waveguides that are optically coupled to the array of waveguides, wherein the second array of waveguide converges into a single waveguide.

64. The composite integrated circuit of claim 59 wherein each of the waveguides in the array of waveguides is etched to produce periodic gratings in between the ends of the waveguide.

65. The composite integrated circuit of claim 59 further comprising:
a lens that accepts optical outputs of the array of waveguides; and
an output waveguide that accepts the lens's optical output.
Add branch waveguides which all combine into one waveguide at a point where they are coupled into fibers somewhere at this point for claim 56.

66. The composite integrated circuit of claim 59 wherein the waveguides of the array are single-mode waveguides.

67. The composite integrated circuit of claim 59 wherein the waveguides of the array are multi-mode waveguides.

68. The composite integrated circuit of claim 59 further comprising:
a mode-locked laser; and
a beam splitter that accepts an optical input from the mode-locked laser and outputs a plurality of optical signals that are optically coupled to the array of waveguides.

69. A composite integrated circuit comprising:
a non-compound semiconductor substrate;
an accommodating layer fabricated over the non-compound semiconductor substrate;
an array of waveguides fabricated over the accommodating layer, wherein the waveguides have a waveguide core made of a gain medium; and
an electro-optic layer formed over the array of waveguides, wherein the electro-optic layer is etched to produce periodic gratings over both ends of the waveguides in the array of waveguides.

70. The composite integrated circuit of claim 69 further comprising electrodes placed over each of the gratings.

71. The composite integrated circuit of claim 69 further comprising isolation trenches etched adjacent to the periodic gratings.

72. The composite integrated circuit of claim 69 further comprising a second array of waveguides that accepts the optical outputs of the array of waveguides.

73. The composite integrated circuit of claim 69 further comprising a second array of waveguide that is optically coupled to the array of waveguides, wherein the second array of waveguides converge into a single waveguide.

74. The composite integrated circuit of claim 69 wherein the electro-optic layer is etched to produce periodic gratings over the array of waveguides in between the ends of each of the waveguides.

75. The composite integrated circuit of claim 69 further comprising:
a lens that accepts optical outputs of the array of waveguides; and
an output waveguide that accepts the lens's optical output.
Add branch waveguides which all combine into one waveguide at a point where they are coupled into fibers somewhere at this point for claim 65.

76. The composite integrated circuit of claim 69 wherein the electro-optic layer is selected from a group consisting of InP and BaTiO₃.

77. The composite integrated circuit of claim 69 wherein the waveguides of the array are single-mode waveguides.

78. The composite integrated circuit of claim 69 wherein the waveguides of the array are multi-mode waveguides.

79. The composite integrated circuit of claim 69 further comprising:
a mode-locked laser; and
a beam splitter that accepts an optical input from the mode-locked laser and outputs a plurality of optical signals that are optically coupled to the array of waveguides.

80. A method for fabricating a tunable laser comprising:
fabricating a non-compound semiconductor substrate;
fabricating an accommodating layer over the non-compound semiconductor substrate;
fabricating a waveguide over the accommodating layer, wherein the waveguide is an electro-optic material and comprises a bottom cladding layer, a waveguide core, and a top cladding layer;
etching periodic gratings into the top surface of the top cladding layer;
placing an electrode over the top cladding layer; and
coupling a controller to the electrode.

81. The method of claim 80 wherein the etching comprises etching the top cladding at both ends, wherein the waveguide core is a gain medium.

82. The method of claim 81 wherein the placing comprises placing the electrode over the gratings at one of the ends of the top cladding and placing a second electrode over the gratings at the other end of the top cladding.

83. The method of claim 82 further comprising coupling a second controller to the second electrode.

84. The method of claim 82 further comprising coupling the second electrode to the controller.

85. The method of claim 80 wherein the etching comprises etching the cladding at both ends and at a portion between both ends to produce periodic gratings.

86. The method of claim 80 further comprising:
fabricating a second waveguide over the accommodating layer, wherein the second waveguide comprises a second bottom cladding layer, a second waveguide core, and a second top cladding layer;
etching the second top cladding layer to produce periodic gratings at the top surface of the second top cladding layer;
placing a second electrode over the second top cladding layer; and
fabricating a gain medium in between and coupled to the waveguide and to the second waveguide.

87. The method of claim 86 further comprising coupling a second controller to the second electrode.

88. The method of claim 86 further comprising coupling the second electrode to the controller.

89. The method of claim 86 further comprising:
fabricating a third waveguide over the accommodating layer, wherein the third waveguide comprises a third bottom cladding layer, a third waveguide core, and a third top cladding layer;
etching the third top cladding layer to produce periodic gratings at the top surface of the third top cladding layer;
placing a third electrode over the third top cladding layer; and
fabricating a second gain medium in between and coupled to the third waveguide and to the second waveguide.

90. The method of claim 89 further comprising coupling a third controller to the third electrode.

91. The method of claim 89 further comprising coupling the third electrode to the controller.

92. The method of claim 80 wherein the waveguide is selected from a group consisting of InP, BaTiO₃, PZT, LiNbO₃, PLZT, plastic, glass, and a combination thereof.

93. The method of claim 80 further comprising accepting as an input at a photodetector two optical signals, each optical signal originating from a single-mode laser, wherein the photodetector produces a millimeter wave output.

94. The method of claim 80 further comprising accepting as an input at a photodetector an optical signal from a multi-mode laser, wherein the photodetector produces a millimeter wave output.

95. The method of claim 80 wherein fabricating a waveguide comprises fabricating a single-mode waveguide.

96. The method of claim 80 wherein fabricating a waveguide comprises fabricating a multi-mode waveguide.

97. A method for fabricating an array of tunable lasers comprising:
fabricating a non-compound semiconductor substrate;
fabricating an accommodating layer over the non-compound semiconductor substrate;
fabricating a first array of waveguides over the accommodating layer, wherein the waveguides in the first array are electro-optic and share a common top surface;
etching the common top surface of the first array of waveguides to produce periodic gratings;
fabricating a second array of waveguides over the accommodating layer, wherein the waveguides in the second array are electro-optic and share a common top surface;
etching the common top surface of the second array of waveguides to produce periodic gratings; and
fabricating a third array of waveguides over the accommodating layer, wherein the third array of waveguides is arranged in parallel in between the first array of waveguides and the second array of waveguides, and coupled thereto.

98. The method of claim 97 further comprising placing individual electrodes over each waveguide in the first array of waveguides and in the second array of waveguides.

99. The method of claim 97 further comprising etching isolation trenches adjacent to the periodic gratings of the first array of waveguides and the second array of waveguides.

100. The method of claim 97 further comprising fabricating a fourth array of waveguides that accepts the optical outputs of the second array of waveguides.

101. The method of claim 97 further comprising:
fabricating a fourth array of waveguides over the accommodating layer, wherein the waveguides in the fourth array share a common top surface;
etching the common top surface of the fourth array to produce periodic gratings; and
fabricating a fifth array of waveguides over the accommodating layer, wherein the waveguides in the fifth array of waveguides are arranged in parallel in between the second array of waveguides and the fourth array of waveguides and coupled thereto.

102. The method of claim 101 further comprising placing an electrode over each of the waveguides in the fourth array of waveguides.

103. The method of claim 97 further comprising:
accepting at a lens optical outputs of the second array of waveguides; and
accepting at an output waveguide the lens's optical output.

104. The method of claim 97 further comprising converging the waveguides of the fourth array into a single waveguide.

105. The method of claim 97 wherein fabricating the first array and fabricating the second array comprise fabricating a first array of single-mode waveguides and fabricating a second array of single-mode waveguides, respectively.

106. The method of claim 97 wherein fabricating the first array and fabricating the second array comprise fabricating a first array of multi-mode waveguides and fabricating a second array of multi-mode waveguides, respectively.

107. The method of claim 97 further comprising:
fabricating a mode-locked laser; and
accepting at a beam splitter an optical input from the mode-locked laser and outputting a plurality of optical signals that are optically coupled to the first array of waveguides.

108. A method for fabricating a tunable laser comprising:
fabricating a non-compound semiconductor substrate;
fabricating an accommodating layer over the non-compound semiconductor substrate;
fabricating a waveguide over the accommodating layer;
forming an electro-optic layer over the waveguide;
etching the electro-optic layer to produce periodic gratings;
placing an electrode over the electro-optic layer above the waveguide; and
coupling a controller to the electrode.

109. The method of claim 108 wherein the etching comprises etching the electro-optic layer at both ends to produce periodic gratings, and wherein the waveguide comprises a waveguide core that is a gain medium.

110. The method of claim 109 wherein placing the electrode comprises placing the electrode over the gratings at one of the ends of the electro-optic layer and further comprising placing a second electrode over the gratings at the other end of the electro-optic layer.

111. The method of claim 110 further comprising coupling a second controller to the second electrode.

112. The method of claim 110 further comprising coupling the second electrode to the controller.

113. The method of claim 108 wherein the etching comprises etching the electro-optic layer at both ends and at a portion between both ends to produce periodic gratings, and wherein the waveguide comprises a waveguide core that is a gain medium.

114. The method of claim 108 further comprising:
fabricating a second waveguide over the accommodating layer;
forming a second electro-optic layer over the second waveguide;
etching the second electro-optic layer to form periodic gratings;
placing a second electrode over the second electro-optic layer; and
fabricating a gain medium in between the waveguide and the second waveguide, and coupled thereto.

115. The method of claim 114 further comprising coupling a second controller to the second electrode.

116. The method of claim 114 further comprising coupling the second electrode to the controller.

117. The method of claim 114 further comprising:
fabricating a third waveguide over the accommodating layer;
forming a third electro-optic layer of the third waveguide;
etching the third electro-optic layer to form periodic gratings;
placing a third electrode over the third electro-optic layer above the third waveguide; and
fabricating a second gain medium in between the third waveguide and the second waveguide, and coupled thereto.

118. The method of claim 117 further comprising coupling a third controller to the third electrode.

119. The method of claim 117 further comprising coupling the third electrode to the controller.

120. The method of claim 108 wherein fabricating the waveguide comprises fabricating the waveguide from a material selected from a group consisting of InP, BaTiO₃, PZT, LiNbO₃, PLZT, plastic, glass, and any combination thereof.

121. The method of claim 108 wherein the electro-optic layer is selected from a group consisting of BaTiO₃, and InGaAsP.

122. The method of claim 108 further comprising accepting at a photodetector as an input two optical signals, each optical signal originating from a single-mode laser, wherein the photodetector produces a millimeter wave output.

123. The method of claim 108 further comprising accepting at a photodetector as an input an optical signal from a multi-mode laser, wherein the photodetector produces a millimeter wave output.

124. The method of claim 108 wherein fabricating the waveguide comprises fabricating a single-mode waveguide.

125. The method of claim 108 wherein fabricating the waveguide comprises fabricating a multi-mode waveguide.

126. A method for fabricating an array of tunable lasers comprising:
fabricating a non-compound semiconductor substrate;
fabricating an accommodating layer over the non-compound semiconductor substrate;
fabricating a first array of waveguides over the accommodating layer;
forming a first electro-optic layer over the first array of waveguides;
etching the first electro-optic layer to produce periodic gratings;
fabricating a second array of waveguides over the accommodating layer;
forming a second electro-optic layer over the second array of waveguides;
etching the second electro-optic layer to produce periodic gratings; and
fabricating an array of gain media over the accommodating layer, wherein the gain media are arranged in parallel in between the first array of waveguides and the second array of waveguides, and are coupled thereto.

127. The method of claim 126 further comprising placing individual electrodes over each waveguide in the first array of waveguides and in the second array of waveguides.

128. The method of claim 126 further comprising etching isolation trenches adjacent to the periodic gratings of the first electro-optic layer and the second electro-optic layer.

129. The method of claim 126 further comprising fabricating a third array of waveguides that accepts the optical outputs of the second array of waveguides.

130. The method of claim 126 further comprising:
fabricating a third array of waveguides over the accommodating layer; and
forming a third electro-optic layer over the third array of waveguides;
etching the third electro-optic layer to produce periodic gratings; and
fabricating a second array of gain media over the accommodating layer, wherein the gain media in the second array of gain media are arranged in parallel in between the second array of waveguides and the third array of waveguides, and are coupled thereto.

131. The method of claim 126 further comprising:
accepting at a lens optical outputs of the second array of waveguides; and
accepting at an output waveguide the lens's optical output.

132. The method of claim 126 further comprising fabricating a third array of waveguides that are optically coupled to the second array of waveguides, wherein the third array of waveguides converge into a single waveguide.

133. The method of claim 126 wherein the first electro-optic layer is selected from a group consisting of InP and BaTiO₃.

134. The method of claim 126 wherein the second electro-optic layer is selected from a group consisting of InP and BaTiO₃.

135. The method of claim 126 wherein the fabricating the first array of waveguides and the fabricating the second array of waveguides comprises fabricating a first array of single-mode waveguides and fabricating a second array of single-mode waveguides, respectively.

136. The method of claim 126 wherein the fabricating the first array of waveguides and the fabricating the second array of waveguides comprises fabricating a first array of multi-mode waveguides and fabricating a second array of multi-mode waveguides, respectively.

137. The method of claim 126 further comprising:
fabricating a mode-locked laser; and
accepting at a beam splitter an optical input from the mode-locked laser and outputting a plurality of optical signals that are optically coupled to the first array of waveguides.

138. A method of fabricating an array of tunable lasers comprising:
fabricating a non-compound semiconductor substrate;
fabricating an accommodating layer over the non-compound semiconductor substrate;
fabricating an array of waveguides over the accommodating layer, wherein the waveguides are electro-optic and share a common top surface; and
etching the common top surface to produce periodic gratings on both ends of each waveguide.

139. The method of claim 138 further comprising placing electrodes over each of the gratings.

140. The method of claim 138 further comprising etching isolation trenches adjacent to the periodic gratings of the array of waveguides.

141. The method of claim 138 further comprising fabricating a second array of waveguides that accept the optical outputs of the array of waveguides.

142. The method of claim 138 wherein the etching comprises etching each of the waveguides in the array of waveguides to produce periodic gratings in between the ends of the waveguide.

143. The method of claim 138 further comprising:
accepting at a lens optical outputs of the array of waveguides; and
accepting at an output waveguide the lens's optical output.

144. The method of claim 138 further comprising fabricating a second array of waveguides that are optically coupled to the array of waveguide, wherein the second array of waveguides converge into a single waveguide.

145. The method of claim 138 wherein the fabricating the array of waveguides comprises fabricating an array of single-mode waveguides.

146. The method of claim 138 wherein the fabricating the array of waveguide comprises fabricating an array of multi-mode waveguides.

147. The method of claim 138 further comprising:
fabricating a mode-locked laser; and
accepting at a beam splitter an optical input from the mode-locked laser and outputting a plurality of optical signals that are optically coupled to the array of waveguides.

148. A method for fabricating an array of tunable lasers comprising:
fabricating a non-compound semiconductor substrate;
fabricating an accommodating layer over the non-compound semiconductor substrate;
fabricating an array of waveguides over the accommodating layer, wherein the waveguides have a waveguide core made of a gain medium;
forming an electro-optic layer over the array of waveguides; and
etching the electro-optic layer to produce periodic gratings over both ends of the waveguides in the array of waveguides.

149. The method of claim 148 further comprising placing electrodes over each of the gratings.

150. The method of claim 148 further comprising etching isolation trenches adjacent to the periodic gratings.

151. The method of claim 148 further comprising accepting at a second array of waveguides the optical outputs of the array of waveguides.

152. The method of claim 148 further comprising etching the electro-optic layer to produce periodic gratings over the array of waveguides in between the ends of each of the waveguides.

153. The method of claim 148 further comprising:
accepting at a lens optical outputs of the array of waveguides; and
accepting at an output waveguide the lens's optical output.

154. The method of claim 148 further comprising fabricating a second array of waveguides that are optically coupled to the array of waveguide, wherein the second array of waveguide converge into a single waveguide.

155. The method of claim 148 wherein the electro-optic layer is selected from a group consisting of InP and BaTiO₃.

156. The method of claim 148 wherein fabricating the array of waveguides comprises fabricating an array of single-mode waveguides.

157. The method of claim 148 wherein fabricating the array of waveguides comprises fabricating an array of multi-mode waveguides.

158. The method of claim 148 further comprising:
fabricating a mode-locked laser; and
accepting at a beam splitter an optical input from the mode-locked laser and outputs a plurality of optical signals that are optically coupled to the array of waveguides.
